(19) United States
(12) Patent Application Publication
(10) Pub. No.: US 2024/0340514 A1
(43) Pub. Date: Oct. 10, 2024

(54) CAMERA DEVICE

(71) Applicant: LG INNOTEK CO., LTD., Seoul (KR)

(72) Inventors: Deok Yong LEE, Seoul (KR); Sung Il LEE, Seoul (KR); Jun Hyeok HONG, Seoul (KR)

(21) Appl. No.: 18/573,177

(22) PCT Filed: Jun. 28, 2022
(86) PCT No.: PCT/KR2022/009242

§ 371 Date: Dec. 21, 2023

(30) Foreign Application Priority Data
Jun. 30, 2021 (KR) 10-2021-0085489

(51) Int. Cl. H04N 23/54; H04N 23/55; H05K 1/14

(52) U.S. Cl. CPC H04N 23/54; H04N 23/55; H05K 1/147; H05K 2201/10151

(57) ABSTRACT

An embodiment of the present invention provides a camera device comprising: a lens holder for accommodating a lens; a housing surrounding the lens holder, a board part including a sensor board, to which an image sensor is mounted from below the housing, and a connection board, which is connected to the sensor board; a base disposed below the board part; and a main board disposed below the base, wherein the connection board has a different thickness than the sensor board.

### TECHNICAL FIELD

The present invention relates to a camera device.

### BACKGROUND ART

A camera is a device which captures an image or moving images of a subject and is mounted on an electronic device such as a portable device, a drone, a vehicle, and the like. In order to improve the quality of an image, a camera module may have an image stabilization (IS) function that corrects or prevents image shakes caused by the movement of a user, an autofocusing (AF) function that automatically adjusts a distance between an image sensor and a lens to arrange a focal length of the lens, and a zooming function that performs zooming to increase or decrease a magnification of an image of a subject at a long distance in order to capture the image.

In addition, camera devices are generally mounted on portable devices such as mobile communication terminals and MP3 players, as well as on electronic devices such as automobiles, endoscopes, and closed-circuit televisions (CCTVs). These camera devices are gradually being developed with a focus on high resolution, and miniaturization and thinning thereof are being progressed. In addition, the camera devices are currently being changed to support various additional functions at low manufacturing costs.

In addition, a camera device includes a lens barrel for accommodating a lens, a lens holder coupled to the lens barrel, an image sensor disposed in the lens holder, and a driving substrate on which the image sensor is mounted. In this case, the lens transmits an image signal of a subject to the image sensor. In addition, the image sensor converts the image signal into an electrical signal. In this case, the accuracy of the image signal is determined in the camera device according to a focal length defined as a distance between the lens and the image sensor.

In addition, the camera device compensates a focus or shakes thereof by relatively moving the lens barrel with respect to the image sensor. That is, in the camera device, the lens barrel accommodating the lens is moved with respect to the image sensor along X, Y, and Z axes. In this case, there is a problem that a structure is complicate because the camera device requires a large number of springs and the like to relatively move the lens barrel. In addition, when the camera device is connected to the image sensor, there are problems of structural stability degradation and spring sensitivity degradation caused by weight.

### Technical Problem

The present invention is directed to providing a camera device with improved operation efficiency due to having a newly structured substrate.

The present invention is also directed to providing a camera device with reduced weight and improved spring sensitivity due to having an electrical wiring structure formed on at least one surface of a connecting substrate.

The present invention is also directed to providing a camera device with optimized impedance and improved structural reliability through a blocking layer and a reinforcement layer.

The present invention is also directed to providing a camera actuator applicable to ultra-slim, ultra-compact, and high-resolution cameras and a camera device.

Objectives to be solved through embodiments are not limited thereto and include objectives or effects understood through the technical solutions or embodiments which will be described below.

### Technical Solution

One aspect of the present invention provides a camera device including a lens holder which accommodates a lens, a housing which surrounds the lens holder, a substrate part including a sensor substrate on which an image sensor is mounted under the housing and a connecting substrate connected to the sensor substrate, a base disposed under the substrate part, and a main substrate disposed under the base, wherein a thickness of the connecting substrate is different from a thickness of the sensor substrate.

The thickness of the connecting substrate may be smaller than the thickness of the sensor substrate.

The sensor substrate may include a plurality of conductive layers and a plurality of bonding layers disposed between or on the plurality of conductive layers.

The sensor substrate may share one conductive layer among the plurality of conductive layers.

The sensor substrate may share one bonding layer among the plurality of conductive layers.

The connecting substrate may include a first connecting part of which one end is in contact with the sensor substrate, a second connecting part connected to the main substrate, and a pattern part disposed between the first connecting part and the second connecting part.

The pattern part may include a first conductive layer shared with the sensor substrate, and the first conductive layer may be formed of a plurality of conductive patterns with separation spaces therebetween.

The pattern part may include an insulating layer disposed between adjacent first conductive layers.

The pattern part may include a first bonding layer shared with the sensor substrate.

The first bonding layer may be in contact with the first conductive layer and be disposed on an inner side of the first conductive layer.

The pattern part may include a reinforcement layer disposed on the first conductive layer.

The pattern part may include a blocking layer disposed under the first bonding layer.

The reinforcement layer may be disposed outside the blocking layer.

The first connecting part may be positioned inside a lower portion of the pattern part.

The pattern part may surround the housing.

The main substrate may be coupled to the base using a bonding member.

### Advantageous Effects

According to an embodiment of the present invention, a camera device with improved drive efficiency can be implemented using a newly structured substrate.

In addition, the present invention can implement a camera device with reduced weight and improved spring sensitivity due to having a wiring structure formed on at least one surface of a connecting substrate.

In addition, the present invention can implement a camera device with optimized impedance and improved structural reliability through a blocking layer and a reinforcement layer.

According to the present invention, a camera actuator applicable to ultra-slim, ultra-compact, and high-resolution cameras and a camera device can be implemented.

Various beneficial advantages and effects of the present invention are not limited to the above-described contents and may be more easily understood in the process of describing specific embodiments of the present invention.

### DESCRIPTION OF DRAWINGS

FIG. 1 is a perspective view of a camera device according to a first embodiment.

FIG. 2 is a view along line AA′ in FIG. 1.

FIG. 3 is an exploded perspective view of the camera device according to the first embodiment.

FIG. 4 is a perspective view of a first actuator in the camera device according to the first embodiment.

FIG. 5 is an exploded perspective view of the first actuator according to the embodiment.

FIG. 6 is a perspective view of a lens holder and a first coil according to the embodiment.

FIG. 7 is a perspective view of a housing and a magnet part according to the embodiment.

FIG. 8 is an exploded perspective view of a first elastic part, the housing, and the lens holder according to the embodiment.

FIG. 9 is an exploded perspective view of a second actuator and a main substrate in the camera device according to the first embodiment.

FIG. 10 is an exploded perspective view of the second camera actuator in the camera device according to the first embodiment.

FIGS. 11 and 12 are perspective views of a coil substrate and an elastic connection part according to the embodiment.

FIG. 13 is a perspective view of a connecting substrate and a sensor substrate according to the embodiment.

FIG. 14 is a plan view of the connecting substrate and the sensor substrate according to the embodiment.

FIG. 15 is a bottom view of the connecting substrate and the sensor substrate according to the embodiment.

FIG. 16 is a view along line BB′ in FIG. 14.

FIG. 17 is a view along line CC′ in FIG. 15.

FIGS. 18 and 19 are conceptual views of the connecting substrate and the sensor substrate according to the embodiment.

FIG. 20A is a cross-sectional view of a pattern part according to the embodiment.

FIG. 20B is a cross-sectional view of a pattern part according to another embodiment.

FIG. 21 is a cross-sectional view of a connecting substrate and a sensor substrate in a camera device according to a second embodiment.

FIG. 22 is a view of a modified embodiment of FIG. 21.

FIG. 23 is a plan view of a connecting substrate and a sensor substrate in a camera device according to a third embodiment.

FIG. 24 is a cross-sectional view along line CC′ in FIG. 23.

FIG. 25 is a cross-sectional view along line DD′ in FIG. 23.

FIG. 26 is a perspective view of a base according to the embodiment.

FIG. 27 is a perspective view of the second actuator according to the embodiment.

FIG. 28 is a perspective view of the second actuator and the main substrate according to the embodiment.

FIGS. 29 to 31 are views for describing operations of the camera device according to the embodiment.

FIG. 32 is a perspective view of a mobile terminal to which the camera device according to the embodiment is applied.

FIG. 33 is a view of a vehicle to which the camera device according to the embodiment is applied.

### MODES OF THE INVENTION

Since the present invention allows various changes and has many embodiments, specific embodiments will be illustrated in the accompanying drawings and described. However, this is not intended to limit the present invention to the specific embodiments, and it is to be appreciated that all changes, equivalents, and substitutes that fall in the spirit and technical scope of the present invention are encompassed in the present invention.

Although the terms “first,” “second,” and the like may be used herein to describe various elements, these elements should not be limited by these terms. These terms are only used to distinguish one element from another element. For example, a second element could be termed a first element, and a first element could similarly be termed a second element without departing from the scope of the present invention. The term “and/or” includes any one or any combination of a plurality of associated listed items.

When a first element is referred to as being “connected” or “coupled” to a second element, it will be understood that the first element may be directly connected or coupled to the second element, or a third element may be present therebetween. In contrast, when an element is referred to as being “directly connected” or “directly coupled” to another element, it will be understood that there are no intervening elements.

Terminology used herein is for the purpose of describing particular embodiments only and is not intended to limit the present invention. The singular forms are intended to include the plural forms, unless the context clearly indicates otherwise. In the present specification, it should be understood that terms such as “comprise,” “including,” or the like specify the presence of stated features, numbers, steps, operations, elements, components, or combinations thereof but do not preclude the presence or addition of one or more other features, numbers, steps, operations, elements, components, or combinations thereof.

Unless otherwise defined, all terms including technical and scientific terms used herein have meanings which are the same as meanings generally understood by those skilled in the art. Terms, such as those defined in commonly used dictionaries, should be interpreted as having meanings that are consistent with their meanings in the context of the relevant art and will not be interpreted in an idealized or overly formal sense unless expressly so defined here.

Hereinafter, when embodiments are described in detail with reference to the accompanying drawings, components that are the same or correspond to each other will be denoted by the same or corresponding reference numerals in all drawings, and redundant descriptions will be omitted.

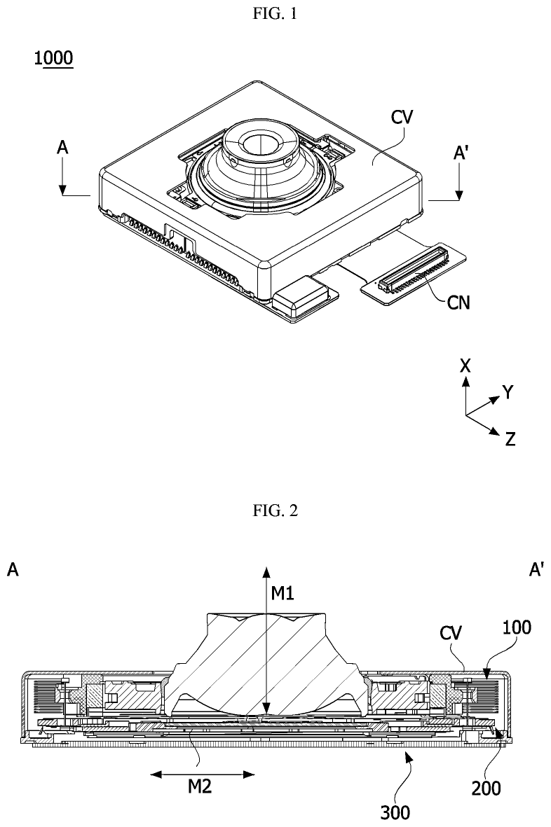

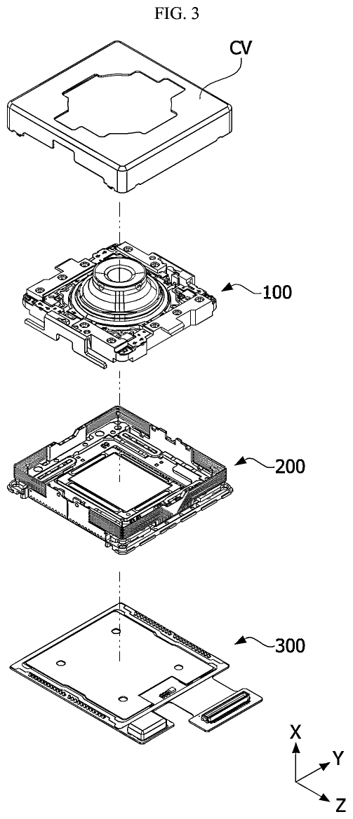

FIG. 1 is a perspective view of a camera device according to a first embodiment, FIG. 2 is a view along line AA′ in FIG. 1, and FIG. 3 is an exploded perspective view of the camera device according to the first embodiment.

### <Camera Device>

Referring to FIGS. 1 to 3, a camera device 1000 according to the first embodiment may include a cover CV, a first actuator 100, a second actuator 200, and a main substrate 300.

The main substrate 300 may be positioned at a lowermost portion in the camera device 1000. In addition, the second actuator 200 may be seated on the main substrate 300. The second actuator 200 may be coupled to the main substrate 300. Accordingly, one end of an image sensor of the second actuator 200, which will be described below, may be coupled to a fixed part which is the main substrate 300.

The camera device 1000 may include actuators. More specifically, the camera device 1000 may include the first actuator 100 and the second actuator 200 in order to move a lens.

The first actuator 100 may be positioned above the second actuator 200. In addition, the second actuator 100 may accommodate the lens. In addition, in the camera device 1000 according to the embodiment, the lens may move in an optical axis direction (X-axis direction) in the first actuator 100. In contrast, in the second actuator 200, the image sensor may move or rotate in a direction perpendicular to the optical axis direction (X-axis direction).

That is, the lens may be moved in the optical axis direction by the first actuator 100. Accordingly, the camera device 1000 may perform autofocusing (AF). In this case, the lens may be coupled to the first actuator 100 at an inner side of the first actuator 100. In this case, a coupling method may include any of adhesive and structural coupling (for example, screw-coupling) methods. In addition, the first actuator 100 may be an AF module.

In addition, the image sensor may be moved or rotated in a direction perpendicular to the optical axis by the second actuator 200. Accordingly, the camera device 1000 may perform optical image stabilization (OIS). In addition, the second actuator 200 may be an OIS module. In addition, the image sensor may be any one among a charge coupled device (CCD), a metal oxide semiconductor (MOS) image sensor, a charge-priming device (CPD), and a charge-injection device (CID). However, the image sensor is not limited to the above-described types.

In addition, in the embodiment, AF is performed using the first actuator 100 which implements a lens shift method, and OIS is performed using the second actuator 200 which implements an image sensor shift method, so that the reliability of the camera device can be improved.

In addition, there is 5-axis hand-shake in the camera device 1000. For example, the 5-axis hand-shake may have two kinds of hand-shake shacking with respect to an angle, two kinds of hand-shake shacking with respect to a shift, and one kind of hand-shake shacking rotationally. In the present embodiment, the sensor shift method may be applied to perform 5-axis OIS and solve a reliability problem of the lens shift method as the above-described camera technology is being developed.

In addition, the first actuator 100 and the second actuator 200 may include various driving parts to move (or rotate) the lens and the image sensor. In the embodiment, the first actuator 100 and the second actuator 200 may include coils and magnets. In addition, the coils and the magnets may generate mutual electromagnetic forces to drive (move or rotate) the lens and the image sensor.

The cover CV may cover at least a part of an outer surface of the first actuator 100 and the second actuator 200. For example, the cover CV may surround the first actuator 100 and the second actuator 200. In addition, the cover CV may be positioned outside the first actuator 100 and the second actuator 200.

In addition, the cover CV may be formed of a material for blocking an electromagnetic wave. For example, the cover CV may be a shield can. Accordingly, the malfunction of the camera device 1000 can be easily prevented. In addition, the cover CV may easily block foreign matter from entering the first actuator 100, the second actuator 200, or the main substrate 300 inside the cover CV.

In addition, the cover CV may include an opening region positioned at one side thereof. Through the opening region, light reflected from an object and the like may be provided to the image sensor in the camera device. In addition, a size of the opening region of the cover CV may be greater than a size of the lens.

In addition, the cover CV may have any of various shapes. For example, the cover CV may have a shape such as a polygonal shape, a circular shape, or the like. In addition, the opening region may have any of various shapes such as a polygonal shape, a circular shape, or the like corresponding to a shape of the lens.

In addition, in the present specification, the optical axis direction corresponds to the X-axis direction. For example, the optical axis direction may be parallel to the X-axis direction. In addition, a second direction and a third direction are directions perpendicular to a first direction. In addition, the second direction and the third direction may be perpendicular to each other. The second direction may correspond to a Y-axis direction. The third direction may correspond to a Z-axis direction.

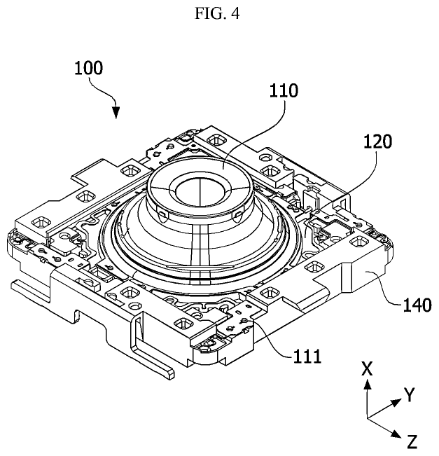

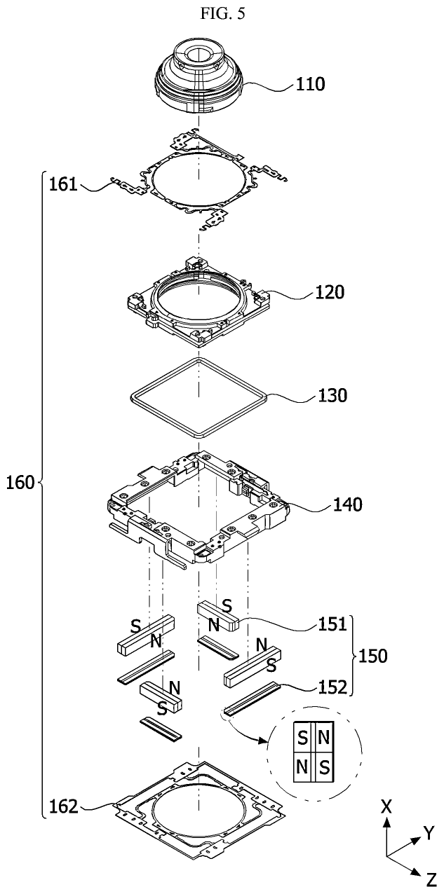

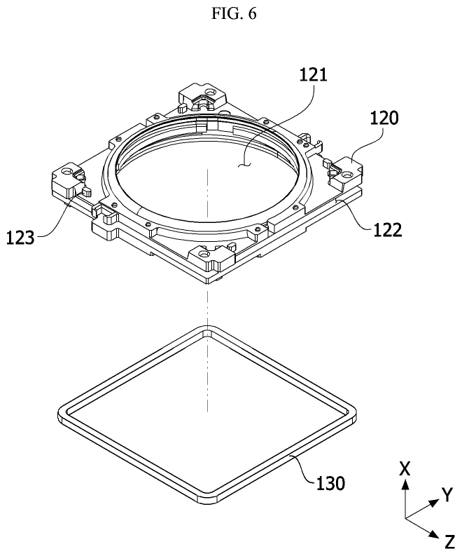

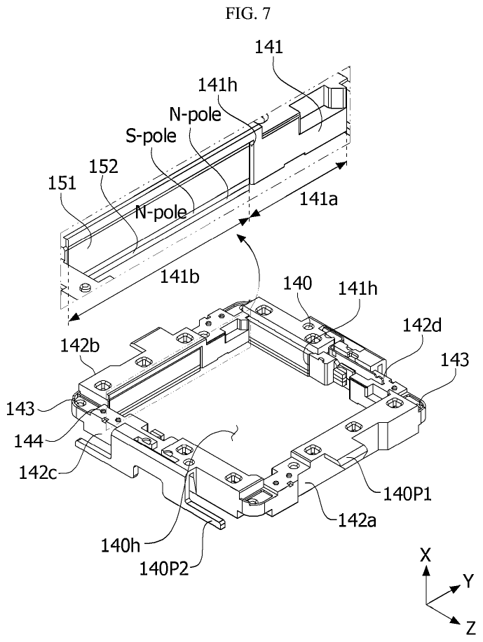

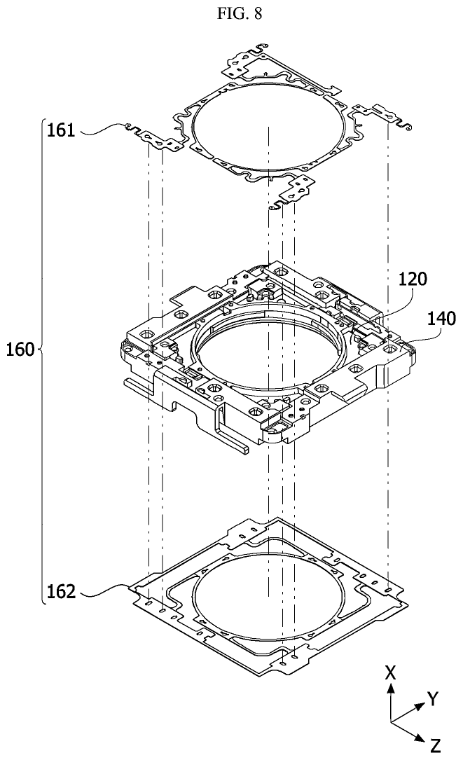

FIG. 4 is a perspective view of the first actuator in the camera device according to the first embodiment, and FIG. 5 is an exploded perspective view of the first actuator according to the embodiment. FIG. 6 is a perspective view of a lens holder and a first coil according to the embodiment, and FIG. 7 is a perspective view of a housing and a magnet part according to the embodiment. FIG. 8 is an exploded perspective view of a first elastic part, the housing, and the lens holder according to the embodiment.

### <First Actuator>

Referring to FIGS. 4 and 5, the first actuator 100 according to the embodiment may include a lens 110, a lens holder 120, a first coil 130, a housing 140, a magnet part 150, and a first elastic part 160. However, the lens 110 may be a component moved by the first actuator 100 and included in the camera device rather than the first actuator. Hereinafter, since the lens holder 120 is moved by the first actuator 100, and the lens 110 is accommodated in the lens holder 120, the present invention will be described based thereon.

The lens 110 may be positioned in the lens holder 120. The lens 110 may be provides as a plurality of lenses 110. In addition, the lens 110 may be positioned on an optical axis and, as described above, may have one of various shapes. In addition, the lens 110 may be coupled to the lens holder 120 to move in the optical axis direction (X-axis direction). Accordingly, AF can be performed.

The lens holder 120 may accommodate the lens 110. In addition, the lens holder 120 may be positioned inside the housing 140. Accordingly, the lens holder 120 may be surrounded by the housing 140. The lens holder 120 may be coupled to the first coil 130. In addition, the lens holder 120 may be driven in the optical axis direction by the magnet part 150 (in particular, a first magnet 151) positioned in the housing 140. In this case, a separation spaces may be present between the lens holder 120 and the housing 140. In addition, the lens holder 120 may be one component of a moving part. In addition, the housing 140 may be a component of a fixed part.

The first elastic part 160 may include a first elastic member 161 and a second elastic member 162. The first elastic member 161 may be positioned on the lens holder 120 and the housing 140. In addition, the second elastic member 162 may be positioned under the lens holder 120 and the housing 140. That is, the first elastic member 161 may be positioned above the second elastic member 162. In addition, the first elastic member 161 may be disposed to be spaced apart from the second elastic member 162 in the optical axis direction (X-axis direction).

The magnet part 150 may include the first magnet 151 and a second magnet 152. The first magnet 151 may be disposed on the second magnet 152. In addition, at least a part of the first magnet 151 may overlap the second magnet 152 in the optical axis direction (X-axis direction).

The first magnet 151 may be provided as a plurality of first magnets 151. In addition, the first magnets 151 may have different polarities. For example, inner sides of the first magnets 151 may have N-poles, and outer sides thereof may have S-poles. Accordingly, the N-poles may be positioned at the inner sides of the first magnets 151 to be closer to the lens than the S-poles. However, the present invention is not limited to these positions. In addition, the N-pole and the S-pole are positioned at only one of the inner side and the outer side. Accordingly, the N-poles of some of the first magnets 151 may be positioned at the inner sides, and the S-poles of the others may be positioned at the inner sides thereof. However, in the present embodiment, the N-poles are disposed at the inner sides thereof and the S-poles are disposed at the outer sides thereof in order to minimize interference with the N-poles and the S-poles.

At least a part of the first magnet 151 may overlap the first coil 130 in the second direction (Y-axis direction) or the third direction (Z-axis direction). Accordingly, a magnitude of an electromagnetic force due to the first magnet 151 and the first coil 130 may increase.

In addition, the second magnet 152 may be positioned under the first magnet 151. For example, the second magnet 152 may include an N-pole and an S-pole. For example, the S-pole of the second magnet 152 may be positioned under the N-pole of the first magnet 151. In addition, the N-pole of the second magnet 152 may be positioned under the S-pole of the first magnet 151. In addition, the S-pole may be positioned under the N-pole of the second magnet 152. In addition, the N-pole may be positioned under the S-pole of the second magnet 152.

Accordingly, a magnetic force of the first magnet 151 applied to a second coil positioned under the second magnet 152 can be minimized. In addition, the second magnet 152 may be spaced apart from the first coil 130 in the first direction (X-axis direction). In addition, the second magnet 152 may not overlap the first coil 130 in the second direction (Y-axis direction) or the third direction (Z-axis direction).

The housing 140 may include an accommodation hole, and the lens holder 120 and the first coil 130 may be positioned in the accommodation hole. That is, the lens holder 120 and the first coil 130 may be positioned inside the housing 140.

In addition, the housing 140 may be disposed to be spaced predetermined distances from the lens holder 120 and the first coil 130.

### <Lens Holder>

Referring to FIG. 6, the lens holder 120 may include a lens accommodation hole 121 as described above. The lens accommodation hole 121 may be formed in any of various shapes. For example, the lens accommodation hole 121 may have a circular shape.

The lens may be positioned inside the lens accommodation hole 121. In addition, a groove or protrusion for coupling may be formed on an outer surface of the lens accommodation hole 121 (an inner surface of the lens holder).

In addition, a first coil seating groove 122 may be formed in an outer surface of the lens holder 120. The first coil seating groove 122 may be formed as a closed loop or an open loop on an YZ plane. For example, the first coil seating groove 122 may be formed as a closed loop along the outer surface of the lens holder 120. The first coil may be seated in the first coil seating groove 122. For example, a diameter or a maximum length of the first coil may be smaller than a diameter or a maximum length of the lens holder. Accordingly, the first coil can be easily coupled to the lens holder 120.

In addition, a holder protrusion 123 may be formed on an upper surface or a lower surface of the lens holder 120. The first elastic part, which will be described below, and the lens holder 120 may be coupled by the holder protrusion 123 or a holder groove. That is, the holder protrusion 123 may be coupled to the first elastic part using a damper member, a bonding member, or the like.

### <Housing and Magnet Part>

Referring to FIG. 7, the housing 140 may be one element (component) of a fixed part of the first actuator 100. The housing 140 may be disposed inside the cover CV.

The housing 140 may include a housing hole 140h positioned in a central portion thereof. The housing hole 140h may have any of various shapes. The housing hole 140h may have a shape corresponding to a shape of the lens holder. For example, the housing hole 140h may have a rectangular hexahedron shape, a quadrangular cross-sectional shape, or a cylindrical shape.

An inner groove 141h may be formed in an inner surface 141 of the housing 140. The inner groove 141h may be provided as a plurality of inner grooves 141h. For example, the number of inner surfaces 141 of the housing 140 may be four. In addition, the number of inner grooves 141h may also be four corresponding to the number of the inner surfaces 141.

The magnet part 150 may be seated in the inner groove 141h of the housing 140. In the embodiment, the first magnet 151 of the magnet part 150 may be positioned on the second magnet 152 which is positioned under the first magnet 151. The magnet part 150 may be coupled to the inner groove 141h of the housing 140 using a bonding member (not shown).

In addition, the magnet part 150 may also be provided as a plurality of magnet parts 150 corresponding to the inner grooves 141h. For example, the number of the first magnets 151 may be four, and the number of second magnets 152 may also be four.

In addition, the housing 140 may include a plurality of outer surfaces. For example, the housing 140 may include a first outer surface 142a to a fourth outer surface 142d. The first outer surface 142a and the second outer surface 142b may be spaced apart from each other in the third direction (Z-axis direction). In addition, the first outer surface 142a and the second outer surface 142b may be positioned to face each other in the third direction (Z-axis direction).

In addition, the third outer surface 142c and the fourth outer surface 142d may be positioned between the first outer surface 142a and the second outer surface 142b. In addition, the third outer surface 142c and the fourth outer surface 142d may be spaced apart from each other in the second direction (Y-axis direction). In addition, the third outer surface 142c and the fourth outer surface 142d may be positioned to face each other in the second direction (Y-axis direction).

The third outer surface 142c and the fourth outer surface 142d may be in contact with the first outer surface 142a and the second outer surface 142b. In addition, the third outer surface 142c and the fourth outer surface 142d may be perpendicularly coupled to the first outer surface 142a and the second outer surface 142b.

In addition, the first outer surface 142a, the second outer surface 142b, the third outer surface 142c, and the fourth outer surface 142d may include protrusions extending outward. For example, first housing steps 140p1 extending outward may be formed on the first outer surface 142a and the second outer surface 142b. The first housing steps 140p1 may be seated on a connecting substrate which will be described below.

In addition, second housing steps 140p2 extending outward may be formed on the third outer surface 142c and the fourth outer surface 142d.

Each of the second housing steps 140p2 may have a structure extending outward and bent downward. Accordingly, unlike the first housing steps 140p1, the second housing steps 140p2 may partially cover an outer surface of the connecting substrate which will be described below. That is, at least a part of the second housing steps 140p2 may overlap the connecting substrate in the second direction (Y-axis direction). In addition, the second housing steps 140p2 may be positioned outside a terminal part (terminal part connected to the main substrate) of the connecting substrate to surround a part of the terminal part. According to such a structure, as soon as the housing 140 is seated on the connecting substrate, the second housing steps 140p2 may protect the terminal part of the connecting substrate. Accordingly, the reliability of the camera device can be improved.

In addition, an upper surface of the housing 140 may include a wire hole 143 in which a wire is accommodated. The wire hole 143 may accommodate the wire (corresponding to an elastic connection part which will be described below). The wire may be coupled to a base, which will be described below, and a coil substrate. That is, all the housing 140, the base, and the coil substrate may be elements of fixed parts through the wire. In addition, since the base and the coil substrate are coupled to the main substrate, all the main substrate, the base, the coil substrate, and the housing 140 may be components of the fixed part.

In addition, the housing 140 may include a housing protrusion 144 formed on the upper surface thereof. The housing protrusion 144 may be provided as a plurality of housing protrusions 144. The plurality of housing protrusions 144 may be formed to protrude upward from the upper surface of housing 140. In addition, a plurality of lower protrusions (not shown) formed to protrude downward may be formed on a lower surface of the housing 140 to correspond to the plurality of housing protrusions 144. The plurality of housing protrusions 144 may be guide protrusions which guide coupling of the first elastic member 161 disposed on the housing 140.

The plurality of housing protrusions 144 may be disposed on four corner regions on the upper surface of housing 140. However, the present invention is not limited thereto, and the housing protrusions 144 may be disposed along an edge of the housing 140.

A predetermined separation space (or gap) may be present between the inner surface 141 of the housing 140 and the outer surface of the lens holder 120.

In addition, a step (no drawing number) may be formed on an inner surface of the housing 140. The step may selectively support the lens holder 120 disposed in the housing hole 140h. In addition, the step may restrict movement of the lens holder 120. For example, the step may perform a stopper function to restrict movement of the lens holder 120 in an upward or downward direction. For example, the lens holder 120 may come into contact with the step when moved to a movement limit.

In addition, as described above, the first actuator 100 in the embodiment may move the lens holder 120 in the optical axis direction (X-axis direction) using four first magnets 151. In addition, magnetic field interference may occur between the first magnet 151 and the second magnet 152. In this case, the first magnet 151 and the second magnet 152 may be fixedly disposed on the housing 140. In addition, the second magnet 152 which drives the second actuator 200 may be fixedly disposed in the housing 140 which is the fixed part other than a moving part. As described above, in the embodiment, the first magnet 151 and the second magnet 152 may be disposed in the inner groove 141h of the housing 140 which is the fixed part. That is, in the embodiment, a coil may be disposed on a component which moves according to lens movement (or shift) and image sensor movement (shift).

In addition, the first magnet 151 and the second magnet 152 may be seated in the inner groove 141h of the inner surface 141. In particular, the inner groove 141h may be positioned at one side of the inner surface 141.

In the embodiment, the inner surface 141 may be divided into a first inner region 141a and a second inner region 141b. The first inner region 141a and the second inner region 141b may be surfaces formed by bisecting the inner surface 141. Most of the inner grooves 141h may be positioned in any one of the first inner region 141a and the second inner region 141b. Accordingly, an amount of an electromagnetic field applied to the connecting substrate by the second coil can be minimized.

### <First Elastic Part>

Referring to FIG. 8, the first elastic part 160 may include the first elastic member 161 and the second elastic member 162. The first elastic member 162 may be positioned above the lens holder 120 and the housing 140. In addition, the second elastic member 162 may be positioned under the lens holder 120 and the housing 140.

The first elastic member 161 and the second elastic member 162 may be coupled to the holder protrusion of the lens holder 120 or the housing protrusion 144. Accordingly, the first elastic member 161 and the second elastic member 162 may connect the housing 140 and the lens holder 120 inside the housing 140. In addition, the lens holder 120 inside the housing 140 may be moved with respect to the housing 140 by an electromagnetic force. In addition, in a case in which an electromagnetic force is not generated, the lens holder 120 may maintain its position inside the housing 140.

For example, when a current flows through the first coil disposed in the first coil seating groove of the lens holder 120, the lens holder 120 may move in the optical axis direction. That is, an AF function can be performed.

In addition, the lens holder 120 may be elastically supported with respect to the housing 140 in a vertical direction by the first elastic member 161 and the second elastic member 162. In addition, the lens holder 120 may be moved in the vertical direction by an electromagnetic interaction between the first magnet and the first coil disposed in the lens holder 120. Accordingly, the lens coupled to the lens holder 120 may move in the optical axis direction.

In addition, the first elastic member 161 and the second elastic member 162 may be plate springs. Each of the first elastic member 161 and the second elastic member 162 may be formed of a metal. Alternatively, each of the first elastic member 161 and the second elastic member 162 may be formed of a non-magnetic material. Accordingly, the first elastic member 161 and the second elastic member 162 may not be affected by magnetic forces of the first magnet and the second magnet and electromagnetic forces of the first coil and the second coil.

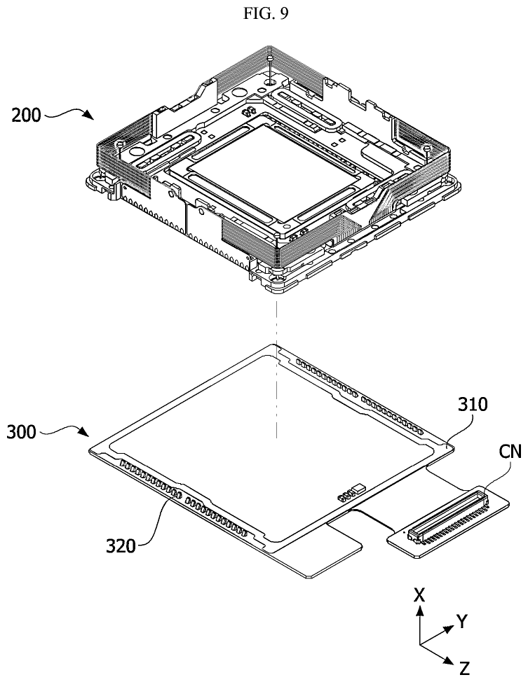

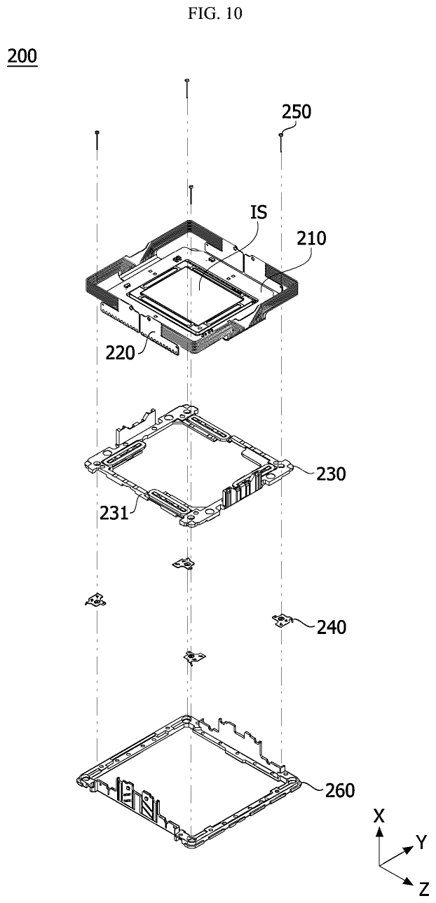

FIG. 9 is an exploded perspective view of the second actuator and the main substrate in the camera device according to the first embodiment, and FIG. 10 is an exploded perspective view of the second camera actuator in the camera device according to the first embodiment.

### <Second Actuator, Main Substrate>

Referring to FIGS. 9 and 10, the second actuator 200 according to the embodiment may be positioned under the first actuator. At least a part of the first actuator may overlap the second actuator 200 in the optical axis direction.

In addition, the second actuator 200 may operate independently of the first actuator. The second actuator 200 may move or rotate the image sensor.

To this end, the second actuator 200 may include an element of a fixed part of which a position is fixed and an element of a moving part of which a position is moved by an electromagnetic force of a second driving part when coupled to the fixed part. In the present specification, fixed parts and moving parts are components of which positions are fixed without being changed by electromagnetic forces generated by the first magnet, the second magnet, the first coil, and the second coil. Conversely, moving parts are components of which positions are changed by the above-described electromagnetic forces. In the first actuator, a fixed part may be the housing. In addition, the housing may be fixedly coupled to the above-described main substrate and cover. Accordingly, each of the main substrate and the cover may also be one element of the fixed part.

In addition, the main substrate 300 may be disposed under the second actuator 200. In particular, the main substrate 300 may be disposed under a base 260. In addition, the main substrate 300 may be coupled to the base. The main substrate 300 may include a main substrate part 310, a terminal part 320, and a connector part CN. The main substrate part 310 may be formed of any of various circuit substrates. The main substrate part 310 may be formed of any of various types, such as a rigid circuit substrate, a flexible circuit substrate, and the like.

The terminal part 320 may be positioned on and electrically connected to the main substrate part 310. In addition, the terminal part 320 may be electrically connected to a connecting terminal positioned on a side surface of the connecting substrate. Soldering may be performed for electrical connection.

In addition, the connector part CN may be positioned outside the second actuator 200. In addition, the first actuator and the second actuator 200 may receive a driving signal from a processor or control unit in an electronic device through the connector part CN.

The first actuator and the second actuator 200 may include fixed parts and moving parts. The second actuator 200 may include substrate parts 210, 220, and 230, a second elastic part 240, an elastic connection part 250, and the base 260.

The fixed part of the second actuator 200 may include the base 260 and at least a part of the substrate parts 210, 220, and 230. In addition, the moving part may include at least another part of the substrate parts 210, 220, and 230.

The substrate parts 210, 220, and 230 according to the embodiment may include a sensor substrate 210, a connecting substrate 220, and a coil substrate 230. The sensor substrate 210 and the connecting substrate 220 may be integrally formed. In addition, the second coil may be seated on the coil substrate 230 and the sensor substrate 210, and the coil substrate 230 and the sensor substrate 210 may move or rotate in the second direction or the third direction.

In addition, the base 260 may be the fixed part of the second actuator 200. In addition, the substrate parts 210, 220, and 230 may be the moving parts of the second actuator 200. The base 260 may be positioned under at least a part of the substrate parts. In addition, the substrate parts may be seated on the base 260.

In this case, the connecting substrate 220 may be the fixed part and also be the moving part. That is, a part of the connecting substrate 220 may be the fixed part, and the remaining part of the connecting substrate 220 may be the moving part. Preferably, one end of the connecting substrate 220 may be connected to the main substrate to serve as the fixed part, and the other end of the connecting substrate 220 may be connected to the sensor substrate 210 to serve as the moving part. This will be described in more detail below.

In addition, the base 260 may have an accommodation space for accommodating components constituting the second actuator 200. Preferably, the base 260 may have an opening region in which at least some of the substrate parts, the image sensor, and the like are accommodated.

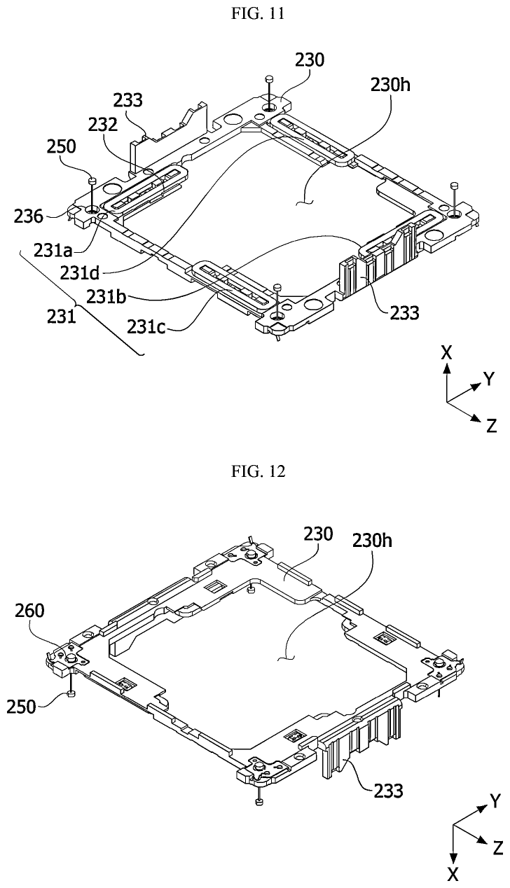

FIGS. 11 and 12 are perspective views of the coil substrate and the elastic connection part according to the embodiment.

### <Coil Substrate, Elastic Connection Part, Second Elastic Part>

Referring to FIGS. 11 and 12, the coil substrate 230 may be disposed under the housing within the base 260. The coil substrate 230 may be supported by the housing through the elastic connection part 250 at a position spaced a predetermined distance from the housing.

That is, one end of the elastic connection part 250 may be positioned in the wire hole of the housing and coupled to a damper fluid (or damper member) and the first elastic part. In addition, the other end of the elastic connection part 250 may be coupled to the coil substrate 230 and the base disposed under the housing.

The elastic connection part 250 may prevent the coil substrate 230 from tilting in a direction different from a moving direction when the second actuator 200 operates. That is, the elastic connection part 250 may prevent the coil substrate 230 from tilting in the optical axis direction regardless of a movement direction of the coil substrate 230. That is, the coil substrate 230 may be relatively moved with respect to the housing or the lens by an interaction between the magnet part (for example, the second magnet) and a second coil 231 while supported by the housing through the elastic connection part 250.

The coil substrate 230 may include the second coil 231 disposed at each corner portion thereof. The second coil 231 may be electrically connected to each of circuit patterns (not shown) included in the coil substrate 230. The second coil 231 may be disposed to face the magnet part disposed in the housing. The second coil 231 may be positioned under the second magnet. In addition, when a current is applied to the second coil 231, an electric field may be generated around the second coil 231. In addition, the coil substrate may be electrically connected to the connecting substrate 220 and the main substrate. In addition, the coil substrate 230 may also be electrically connected to an external electronic device through the connector part.

The coil substrate 230 may include a coil substrate hole 230h in which an image sensor IS or a part of the sensor substrate 210 may be positioned. The coil substrate hole 230h may be an opening region. The coil substrate hole 230h may accommodate the image sensor IS or a filter and may be spaced a predetermined distance therefrom in the first direction (X-axis direction). That is, light passing through the coil substrate hole 230h may be provided to the image sensor IS.

The second coil 231 may be provided as a plurality of second coils 231. For example, the second coils 231 may include four coils. In the embodiment, the coil substrate 230 may include second coil seating grooves 232 in which the plurality of second coils 231 are seated. The second coil seating grooves 232 may be formed in an upper surface of the coil substrate 230. The second coil seating grooves 232 may be positioned to correspond to housing grooves of the housing above the coil substrate 230. That is, the second coil seating grooves 232 may be positioned at corners of the coil substrate 230.

In addition, a current may be independently applied to at least one coil among the four second coils. However, the present invention is not limited thereto, and a current may be applied to the four second coils 231 in various methods. For example, in the first embodiment, the second coils 231 may be controlled through three channels. Alternatively, in a second embodiment, second coils 231 may be controlled through four individual channels. Accordingly, the four second coils 231 may be electrically isolated from each other. Any one of a forward current and a reverse current may be selectively applied to each of the four second coils 231. In the present embodiment, at least only one of the four coils is electrically isolated, and the remaining coils may be electrically connected to another coil. Alternatively, all four coils constituting the second coils 231 may be electrically isolated from each other. Alternatively, every two of the four coils may form channels. In this case, when only three of the four coils are electrically isolated, three pairs of wires, that is, six wires, may be withdrawn from three coils. In addition, when all four coils are electrically isolated, a total of four pairs of wires, that is, eight wires, may be withdrawn from the four coils.

In addition, the four second coils 231 may be positioned under the second magnets described above. That is, the second coils 231 may be positioned to correspond to the second magnets. In the embodiment, at least a part of the second coil 231 may overlap the second magnet thereabove in the first direction (X-axis direction). In addition, at least a part of the second coil 231 may overlap both the N-pole and the S-pole positioned under the second magnet in the first direction (X-axis direction). Accordingly, the second coil 231 may be positioned at each corner of the coil substrate 230. In addition, the second coil 231 may be positioned in one side region in the inner surface of the housing.

In the embodiment, the second coils 231 may include a first sub-coil 231a, a second sub-coil 231b, a third sub-coil 231c, and a fourth sub-coil 231d.

The first sub-coil 231a may be disposed in a first corner of the coil substrate 230. The second sub-coil 231b may be disposed in a second corner of the coil substrate 230. The third sub-coil 231c may be disposed in a third corner of the coil substrate 230. The fourth sub-coil 231d may be disposed in a fourth corner of the coil substrate 230. The first sub-coil 231a and the second sub-coil 231b may be disposed in a first diagonal direction of the coil substrate 230, and the third sub-coil 231c and the fourth sub-coil 231d may be disposed in a second diagonal direction of the coil substrate 230. That is, the first corner and the second corner may be positioned in the first diagonal direction. In addition, the third corner and the fourth corner may be positioned in the second diagonal direction.

In the embodiment, the first sub-coil 231a and the second sub-coil 231b may be disposed to extend in the second direction (Y-axis direction). The third sub-coil 231c and the fourth sub-coil 231d may be disposed to extend in the third direction (Z-axis direction).

Accordingly, a long side of the first sub-coil 231a and a long side of the second sub-coil 231b may be disposed parallel to each other. A long side of the third sub-coil 231c and a long side of the fourth sub-coil 231d may be disposed parallel to each other. The long side of the first sub-coil 231a and the long side of the third sub-coil 231c may be disposed unparallel to each other. In this case, the long side of the first sub-coil 231a and the long side of the third sub-coil 231c may be disposed so that a virtual extension lines thereof are perpendicular to each other. An arrangement direction of the first sub-coil 231a and an arrangement direction of the third sub-coil 231c may be perpendicular to each other.

In the present embodiment, a current may be independently applied to at least one coil among the first sub-coil 231a to the fourth sub-coil 231d. In addition, the first sub-coil 231a to the fourth sub-coil 231d may be electrically isolated from each other.

Meanwhile, Hall sensors may be disposed inside or outside the first sub-coil 231a to the fourth sub-coil 231d. In this case, in the embodiment, the Hall sensors may be disposed inside only three coils among the first sub-coil 231a to the fourth sub-coil 231d. That is, when the first sub-coil 231a to the fourth sub-coil 231d are controlled through three channels in one embodiment, a Hall sensor may not be provided at one coil.

In addition, each of the Hall sensors may detect a magnetic force of the magnet part. Movement of an image sensor module may be checked in real time through the magnetic force of the magnet part detected by the Hall sensor. In addition, an AF feedback control or OIS feedback control can be performed using the Hall sensor.

In addition, the Hall sensor may be provided as a plurality of Hall sensors. That is, the Hall sensors may include three sensors. Movement in the X-axis direction, movement in the Y-axis direction, and movement in the Z-axis direction of the image sensor IS may all be detected using the three sensors. The Hall sensors may be positioned to correspond to the first and second magnets. In addition, the Hall sensors may be positioned adjacent to the first and second magnets.

A driver integrated circuit (IC, not shown) for controlling operations of the first and second actuators may be disposed on the coil substrate 230, the sensor substrate 210, or the main substrate.

In addition, various passive elements or active elements may be disposed on the above-described substrate parts to operate of the second actuator.

In this case, the substrate parts may be electrically connected to the drivers IC, the passive elements, and the active elements. Finally, the substrate parts may also be electrically connected to an external electronic device through a connector.

In addition, the coil substrate 230 may include a housing support part 233 extending upward. The housing support part 233 may extend from the coil substrate 230 in the first direction (X-axis direction). In addition, the coil substrate 230 may be coupled to the sensor substrate thereunder.

In addition, the housing support part 233 may support the first housing step. Accordingly, at least a part of the housing support part 233 may overlap the first housing step in the first direction (X-axis direction). In addition, an outermost side surface of the first housing step may be positioned outside the housing support part 233. However, the housing is an element of a fixed part coupled to the cover, and the coil substrate 230 is one element of a moving part to be moved for an OIS function. Accordingly, the housing (first housing step) is supported by the housing support part 233 but is not coupled thereto. For example, the housing support part 233 may also serve as a stopper or the like. In addition, the cover may be coupled to the main substrate. Accordingly, the main substrate may also be an element of a fixed part.

In addition, the coil substrate 230 may include the second elastic part 240 disposed on a lower surface of the coil substrate 230. The second elastic part 240 may be positioned at each corner of the coil substrate 230. In addition, the coil substrate 230 may include a connecting hole 236 in which the elastic connection part 250 may be accommodated. The connecting hole 236 may also be disposed in each corner of the coil substrate 230. In addition, the elastic connection part 250 may be accommodated in the connecting hole 236. The elastic connection part 250 may also be coupled to the second elastic part 240. In addition, the elastic connection part 250 may also be coupled to the above-described housing.

In the embodiment, one end of the elastic connection part 250 may be coupled to the housing, and the other end thereof may be coupled to the coil substrate 230. Accordingly, the housing and the coil substrate 230 may be coupled to each other. However, even when the coil substrate 230 moves with the sensor substrate, in a state in which an electromagnetic force due to the second coil is not generated, positions of the coil substrate and the housing may be maintained by the elastic connection part 250.

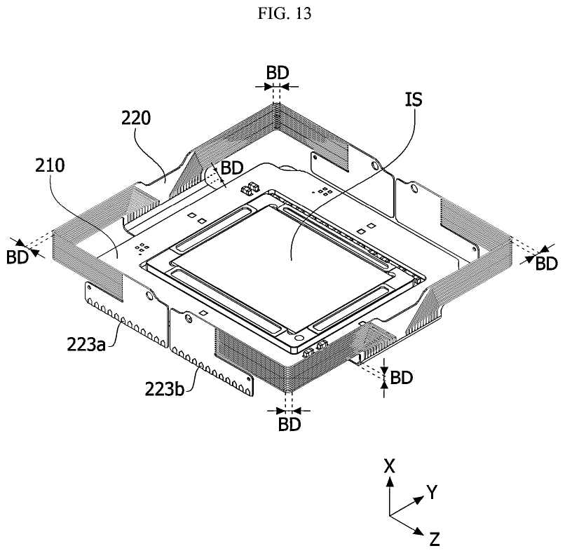

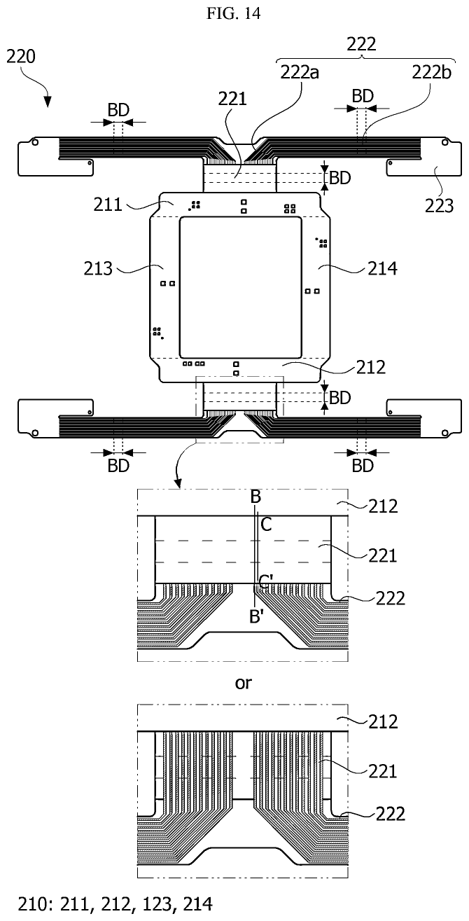

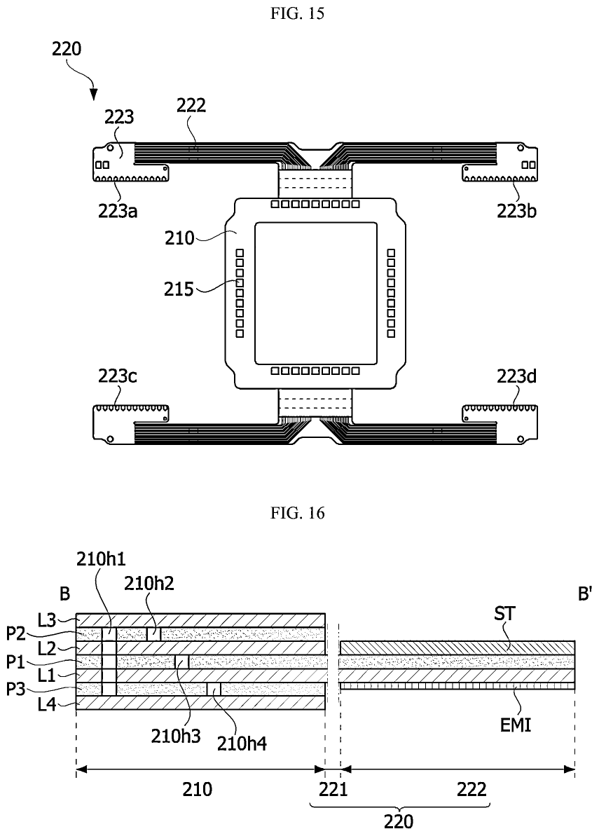

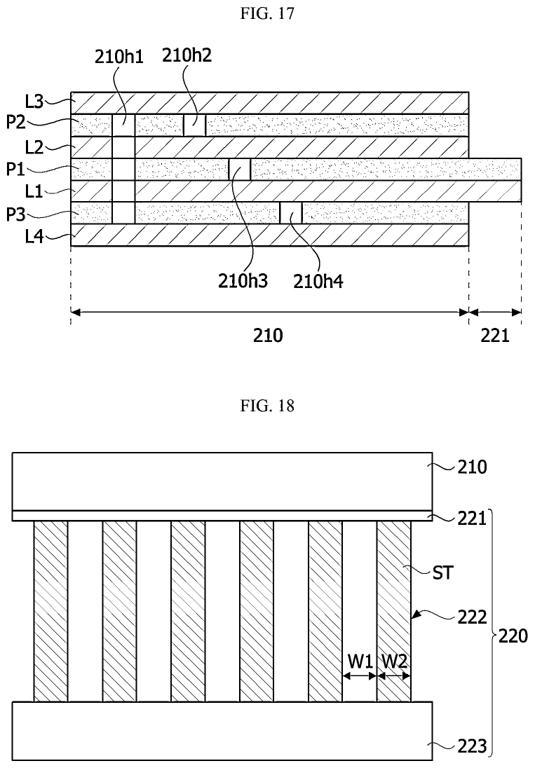

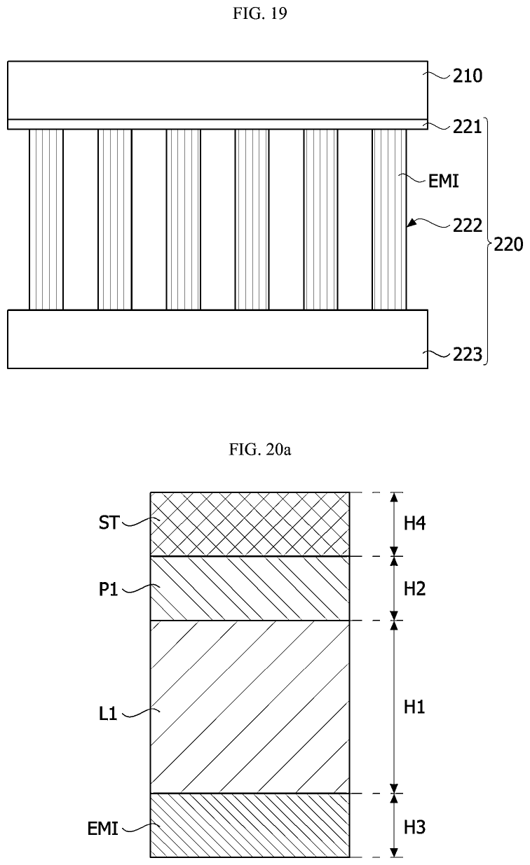

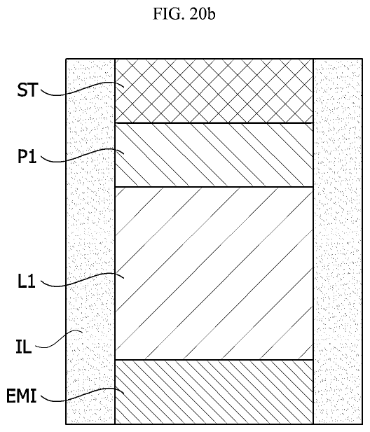

FIG. 13 is a perspective view of the connecting substrate and the sensor substrate according to the embodiment, and FIG. 14 is a plan view of the connecting substrate and the sensor substrate according to the embodiment. FIG. 15 is a bottom view of the connecting substrate and the sensor substrate according to the embodiment, and FIG. 16 is a view along line BB′ in FIG. 14. FIG. 17 is a view along line CC′ in FIG. 15, and FIGS. 18 and 19 are conceptual views of the connecting substrate and the sensor substrate according to the embodiment. FIG. 20A is a cross-sectional view of a pattern part according to the embodiment, and FIG. 20B is a cross-sectional view of a pattern part according to another embodiment.

### <Connecting Substrate and Sensor Substrate>

Referring to FIGS. 13 to 15, the connecting substrate 220 and the sensor substrate 210 according to the embodiment may be coupled to the above-described coil substrate. The coil substrate may be positioned on the sensor substrate 210 and inside the connecting substrate 220.

According to such a structure, when a current flows through the coil of the coil substrate and then an electromagnetic force is generated, the coil substrate may move. In addition, the connecting substrate and the sensor substrate connected to the coil substrate may also move. That is, the image sensor IS of the sensor substrate 210 may be moved in the second direction (Y-axis direction) or the third direction (Z-axis direction) or axially moved by the second coil of the coil substrate.

The sensor substrate 210 may be positioned under the coil substrate. At least a part of the coil substrate may overlap the sensor substrate 210 in the first direction (X-axis direction).

According to the embodiment, the sensor substrate 210 and the connecting substrate 220 may be integrally formed in the substrate parts. The connecting substrate 220 may be positioned outside the sensor substrate 210.

First, the sensor substrate 210 may be coupled to the coil substrate using an epoxy, electrical soldering, or the like. In addition, at least a part of the coil substrate hole of the coil substrate may overlap the image sensor IS in the first direction.

The sensor substrate 210 may be positioned under the housing, and the image sensor may be mounted on the sensor substrate 210. That is, the image sensor IS may be seated on an upper surface of the sensor substrate 210. In addition, the sensor substrate 210 may further include a filter positioned above the image sensor IS. Accordingly, light may be provided to the image sensor IS through the filter. The filter may serve to block light in a certain frequency band that passes through the lens from being incident on the image sensor IS. A filter 440 may be positioned parallel to the YZ plane. The filter 440 may be disposed between the lens and the image sensor IS. The filter 440 may include an infrared filter. The infrared filter may absorb or reflect infrared light incident on the infrared filter. However, the present invention is not limited thereto.

The sensor substrate 210 may be a package substrate. That is, the image sensor IS may be mounted on the sensor substrate 210 in a package type. The sensor substrate 210 may include a printed circuit board (PCB).

In the present embodiment, the sensor substrate 210 may be a rigid PCB. In addition, the sensor substrate 210 may include a circuit board. The image sensor IS may be disposed on the sensor substrate 210. The sensor substrate 210 may be coupled to the coil substrate 230. To this end, the side surface of the coil substrate may be electrically connected to the connecting substrate. In addition, the coil substrate may be coupled to the sensor substrate using a bonding member such as an epoxy.

In addition, the sensor substrate 210 may be electrically connected to the image sensor IS, and a signal received from the image sensor IS may be provided along the sensor substrate 210 and the connecting substrate 220 connected to the sensor substrate 210. In addition, one end of the connecting substrate 220, which will be described below, may be connected to the sensor substrate 210, and the other end thereof may be connected to the main substrate. That is, the connecting terminal is formed on the other end of the connecting substrate 220, and the connecting terminal may be electrically connected to the terminal part of the main substrate through soldering or the like

In addition, a thickness of the sensor substrate 210 may be different from a thickness of the connecting substrate 220. For example, the thickness of the sensor substrate 210 may be greater than the thickness of the connecting substrate 220. In addition, the sensor substrate may include a plurality of conductive layers and a plurality of bonding layers disposed between or on the plurality of conductive layers. This will be discussed below.

In addition, the image sensor IS may be a component on which an image is formed by light passing through the lens and the filter 440 and incident thereon. That is, the image sensor IS may convert a received light signal into an electrical signal.

In addition, the image sensor IS may be electrically connected to the sensor substrate 210 as described above. As an example, the image sensor IS may be coupled to the sensor substrate 210 through a surface mounting technology (SMT). As another example, the image sensor IS may be coupled to the sensor substrate 210 through a flip chip technology. Any of various coupling methods may be applied thereto. The image sensor IS may be electrically connected to a sensor terminal part 215 of a lower surface of the sensor substrate 210.

In addition, the image sensor IS may be disposed so that an optical axis of the image sensor IS matches an optical axis of the lens. That is, the optical axis of the image sensor IS and the optical axis of the lens may be aligned. In addition, the image sensor IS may convert light emitted to an effective image region of the image sensor IS into an electrical signal. In addition, the converted electrical signal may be an image signal. The image sensor IS may be any one among a CCD, a MOS image sensor, a CPD, and a CID.

In addition, as described above, when the coil substrate is driven, the image sensor IS may be driven in response to the driving of the coil substrate, and the sensor substrate coupled to the coil substrate and the connecting substrate may also be driven in response to the driving of the coil substrate. Accordingly, the image sensor IS on the sensor substrate may also move according to operation of the coil substrate.

The sensor substrate 210 may include a first edge region 211, a second edge region 212, a third edge region 213, and a fourth edge region 214 which are regions other than the image sensor IS.

Accordingly, the first edge region 211, the second edge region 212, the third edge region 213, and the fourth edge region 214 may not overlap the image sensor IS in the first direction.

In addition, the first edge region 211 and the second edge region 212 may be disposed to be spaced apart from each other in the third direction (Z-axis direction). In addition, the first edge region 211 and the second edge region 212 may be positioned to face each other in the third direction (Z-axis direction). The first edge region 211 and the second edge region 212 may have long sides in the second direction (Y-axis direction).

The third edge region 213 and the fourth edge region 214 may be disposed to be spaced apart from each other in the second direction (Y-axis direction). In addition, the third edge region 213 and the fourth edge region 214 may be positioned to face each other in the second direction (Y-axis direction). In addition, the third edge region 213 and the fourth edge region 214 may have long sides in the third direction (Z-axis direction).

According to the embodiment, the connecting substrate 220 may be connected to the first edge region 211 and the second edge region 212.

In addition, the connecting substrate 220 may include a first connecting part 221, a pattern part 222, and a second connecting part 223.

The first connecting part 221 may be in contact with the first edge region 211 and the second edge region 212 of the sensor substrate 210. In addition, the first connecting part 221 may extend from the first edge region 211 and the second edge region 212 and include a bending region BD. In the present specification, the bending region BD may be a region having a curvature to be bent at a predetermined angle. In addition, for example, an extending direction may be changed vertically due to the bending region. The bending region BD may be positioned in each of the first connecting part 221 and the pattern part 222.

At least a part of the first connecting part 221 may overlap the sensor substrate 210 on the YX plane. For example, the first connecting part 221 may overlap the sensor substrate 210 in the third direction (Z-axis direction). A length of the first connecting part 221 may be smaller than a length of the sensor substrate 210 in the first direction. A detailed structure thereof will be described below.

In addition, the pattern part 222 may include a first sub-pattern part 222a extending in the first direction and a second sub-pattern part 222b extending to surround a side surface of the housing. One end of the first sub-pattern part 222a is in contact with the sensor substrate 210, and the other end thereof is in contact with the second sub-pattern part 222b. In addition, one end of the second sub-pattern part 222b may be in contact with the first sub-pattern part 222a, and the other end thereof may be in contact with the second connecting part 223.

In the embodiment, the pattern part 222 may have a pattern. For example, the pattern part 222 may include a plurality of patterns. The pattern may be a layer including a line for electrical connection.

The second connecting part 223 may include connecting terminals 223a to 223d. The connecting terminals may include a first connecting terminal 223a to a fourth connecting terminal 223d. The number of terminals may be the same for each of the first connecting terminal 223a to the fourth connecting terminal 223d. In addition, the first connecting terminal 223a and the second connecting terminal 223b may be positioned on the second connecting part 223 extending through the first connecting part in contact with the first edge region 211. In addition, the third connecting terminal 223c and the fourth connecting terminal 223d may be positioned on the second connecting part 223 extending through the first connecting part in contact with the second edge region 212.

As a modified embodiment, a pattern (or pattern layer) of a pattern part 222 may extend to a first connecting part 221. As described above, the pattern part 222 may include a conductive line for electrical connection between a sensor substrate 210 and a main substrate. To this end, the conductive line which transmits an electrical signal may be provided as a plurality of conductive lines. In addition, among the conductive lines, adjacent conductive lines may be disposed to be spaced apart from each other. In other words, among the plurality of conductive lines, separation spaces may be present between the adjacent conductive lines. In addition, the plurality of conductive lines may be conductive lines extending from a sensor substrate 210. That is, the conductive lines in a connecting substrate 220 may extend or may be connected from a plurality of conductive layers or conductive lines of the sensor substrate 210. According to such a structure, a thickness of the sensor substrate 210 may be greater than a thickness of the connecting substrate 220. Accordingly, performance degradation of driving or shift of the sensor substrate 210 can be solved. In other words, a weight of the connecting substrate 220 can be reduced by reducing a thickness of the connecting substrate 220. Accordingly, a weight of the sensor substrate and a weight of the connecting substrate can be reduced to improve the performance of shift and driving of an image sensor.

In addition, in the embodiment, the sensor substrate 210 may be a double-sided lamination substrate. For example, the sensor substrate 210 may be a flexible copper clad laminate (FCCL).

On the other hand, the connecting substrate 220 may be a laminated substrate of which only one surface is used. For example, the connecting substrate 220 may have a structure of which one side has conductive lines (or a conductive layer) formed of copper by etching the copper. In addition, a layer of an alloy material may be formed on the etched or removed conductive lines (or conductive layer). Due to such a layer, the spring sensitivity of the connecting substrate 220 can be optimized. In addition, a reinforcement plate or reinforcement layer may be further disposed on the connecting substrate 220 as described below to improve movement performance of the sensor substrate 210. That is, an optimal design for driving sensitivity can be achieved. In addition, a blocking layer may be further disposed on the connecting substrate 220. In addition, the effect due to an electromagnetic force generated by the coil or the magnet part inside the connecting substrate 220 can be minimized by the blocking layer. In addition, an impedance of an electrical line, that is, the conductive layer, can be optimized by the blocking layer. That is, the blocking layer may be positioned on an inner side of the connecting substrate, and the reinforcement plate (or reinforcement layer) may be positioned on an outer side of the connecting substrate. Accordingly, the blocking layer may also be positioned on an inner side of the reinforcement plate (or reinforcement layer).

In addition, the connecting substrate 220 may be a flexible PCB.

However, in a modified embodiment, both a sensor substrate 210 and a connecting substrate 220 may be flexible PCBs. Accordingly, the flexibility of a camera device can be improved. In addition, the above-described content may be equally applied to a structure of the sensor substrate 210 and the connecting substrate 220 in the modified embodiment.

Referring to FIGS. 16 and 17, each of the sensor substrate 210 and the connecting substrate 220 according to the embodiment may be formed of a plurality of layers.

The sensor substrate 210 may include at least one conductive layer among conductive layers L1 to L4 and at least one bonding layer P1 positioned on at least one conductive layer among the conductive layers L1 to L4. In addition, as described above, the sensor substrate 210 may be a rigid PCB and may further include an additional insulating member, insulating layer, or the like in addition to the bonding layer.

First, the sensor substrate 210 may include a first conductive layer L1, a second conductive layer L2, a third conductive layer L3, and a fourth conductive layer L4. In addition, the sensor substrate 210 may include a first bonding layer P1, a second bonding layer P2, and a third bonding layer P3.

The first bonding layer P1 may be disposed between the first conductive layer L1 and the second conductive layer L2. The second bonding layer P2 may be disposed between the second conductive layer L2 and the third conductive layer L3. The third bonding layer P3 may be disposed between the first conductive layer L1 and the fourth conductive layer L4.

In addition, the sensor substrate 210 may include at least one conductive hole. The conductive hole may be a passage for electrical connection between the first conductive layer L1 to the fourth conductive layer L4 spaced apart from each other in a thickness direction.

For example, the sensor substrate 210 may include a first conductive hole 210h1 to a fourth conductive hole 210h4. The first conductive hole 210h1 may connect the third conductive layer L3 and the fourth conductive layer L4. Accordingly, the first conductive hole 210h1 may pass through the conductive layers and the bonding layers positioned between the third conductive layer L3 and the fourth conductive layer L4.

The second conductive hole 210h2 may electrically connect the third conductive layer L3 and the second conductive layer L2. Accordingly, the second conductive hole 210h2 may pass through the second bonding layer P2.

In addition, the third conductive hole 210h3 may electrically connect the first conductive layer L1 and the second conductive layer L2. The third conductive hole 210h3 may pass through the first bonding layer P1.

In addition, the fourth conductive hole 210h4 may electrically connect the first conductive layer L1 and the fourth conductive layer L4. The fourth conductive hole 210h4 may pass through the third bonding layer P3.

However, the present invention is not limited to such conductive holes, and an additional conductive hole may be further disposed in the sensor substrate for electrical connection between the conductive layers spaced apart from each other in the thickness direction.

In addition, as described above, the connecting substrate 220 may include the first connecting part 221, the pattern part 222, and the second connecting part 223. In this case, the present invention will be described, but the second connecting part 223 will not be described. In addition, the pattern part 222 may be positioned between the first connecting part 221 and the second connecting part 223.

Some layers in the connecting substrate 220 may be the same as some layers in the sensor substrate 210. That is, the connecting substrate 220 and the sensor substrate 210 may share at least one layer with each other. In the embodiment, among the plurality of conductive layers, the sensor substrate may share one conductive layer with the connecting substrate 220. In addition, among the plurality of conductive layers, the sensor substrate may share one bonding layer with the connecting substrate 220. For example, one conductive layer may be positioned in both the sensor substrate 210 and the connecting substrate 220. In addition, one bonding layer may also be positioned in both the sensor substrate 210 and the connecting substrate 220. That is, one conductive layer may overlap the sensor substrate 210 and the connecting substrate 220. In addition, one bonding layer may overlap the sensor substrate 210 and the connecting substrate 220.

For example, the first conductive layer L1 may be positioned in both the sensor substrate 210 and the connecting substrate 220. That is, the first conductive layer L1 may be a layer shared by the pattern part (or the connecting substrate) and the sensor substrate. In addition, the first bonding layer P1 may be positioned in both the sensor substrate 210 and the connecting substrate 220. That is, the first bonding layer P1 may be a layer shared by the pattern part (or the connecting substrate) and the sensor substrate. In this case, as described above, the number of the conductive layers in the connecting substrate 220 may be smaller than or equal to the number of the conductive layers in the sensor substrate 210. Accordingly, the thickness of the connecting substrate 220 may be smaller than the thickness of the sensor substrate 210. Accordingly, the connecting substrate 220 may include the conductive layer electrically connected to the sensor substrate 210 so that a thickness of the connecting substrate 220 can be reduced. According to such a structure, a weight of the connecting substrate 220 can be reduced. Accordingly, driving efficiency for OIS can be improved in the camera device.

In addition, the first conductive layer L1 may be in contact with the first bonding layer P1 and be disposed outside the first bonding layer P1. That is, the first bonding layer P1 may be positioned inside the first conductive layer L1.

In addition, in the connecting substrate 220 according to the embodiment, a blocking layer EMI and a reinforcement layer ST may be positioned in the pattern part.

The reinforcement layer ST may be positioned on the first bonding layer P1 in the connecting substrate 220 or the pattern part 222. In addition, the blocking layer EMI may be positioned under the first conductive layer L1 in the connecting substrate 220 or the pattern part 222. The reinforcement layer ST and the blocking layer EMI may be spaced apart from each other in the thickness direction. In addition, the first conductive layer L1 and the first bonding layer P1 may be positioned between the reinforcement layer ST and the blocking layer EMI.

The above-described conductive layer may serve as an electrical line which transmits an electrical signal and may be formed of a material having high electrical conductivity. For example, the conductive layer may be formed of at least one metal material selected from gold (Au), silver (Ag), platinum (Pt), titanium (Ti), tin (Sn), copper (Cu), and zinc (Zn). In addition, the bonding layer may be formed of a fiber-reinforcing material such as elastic fiber and glass fiber and a synthetic resin such as an epoxy resin for a bonding force between the conductive layer and the other layer. That is, the bonding layer may be a bonding member having good mechanical and thermal properties.

In addition, the reinforcement layer ST may be formed of any of various metals and metal alloys to improve mechanical reliability. For example, the reinforcement layer ST may be a binary alloy or ternary alloy including copper. For example, the reinforcement layer ST may be a binary alloy of copper (Cu)-nickel (Ni). For example, the reinforcement layer ST may be a binary alloy of copper (Cu)-tin (Sn). For example, the reinforcement layer ST may be a binary alloy of copper (Cu)-beryllium (Be). For example, the reinforcement layer ST may be a binary alloy of copper (Cu)-cobalt (Co). For example, the reinforcement layer ST may be a ternary alloy of copper (Cu)-nickel (Ni)-tin (Sn). For example, the reinforcement layer ST may be a ternary alloy of copper (Cu)-beryllium (Be)-cobalt (Co). As described above, the reinforcement layer ST may be formed of one of various materials.

In addition, a part of the reinforcement layer ST may be inserted into the sensor substrate 210. Alternatively, at least a part of the reinforcement layer ST may be positioned on the sensor substrate 210. Accordingly, the reinforcement layer ST may be positioned in a plurality of layers of the sensor substrate 210.

In addition, as described above, in the pattern part 222, the conductive layer and the bonding layer may be disposed to be spaced apart from a conductive layer and a bonding layer that are adjacent thereto. Accordingly, the pattern part 222 may be formed of the pattern layer. The pattern layer may be formed of the conductive layer and the bonding layer.

In the pattern part 222, each conductive layer may be connected to an electrical line connected to the image sensor or the driving driver on the sensor substrate 210. In addition, in the pattern part 222, each conductive layer, that is, an electrical line, may be electrically connected to the main substrate through the connecting terminal of the second connecting part 223.

In addition, there may be an empty space between the spaced conductive layers (conductive lines and conductive patterns) or the bonding layers (bonding lines and bonding layers). However, the reinforcement layer ST may be disposed in the empty space. Alternatively, the blocking layer EMI may be positioned in the above-described empty space.

Referring to FIGS. 18 and 19, as described above, the connecting substrate 210 may be in contact with and electrically connected to the first connecting part 221. A thickness of the first connecting part 221 and the thickness of the sensor substrate 210 may be different from each other. Accordingly, the first connecting part 221 and the sensor substrate 210 may have a stepped structure. In addition, at least one conductive layer in the first connecting part 221 may be the same as a layer of the sensor substrate 210.

In addition, in the pattern part 222, electrical lines may be spaced apart from each other unlike in the first connecting part 221. As described above, the conductive layer in pattern part 222 may be spaced a predetermined distance from an adjacent conductive layer. Accordingly, the electrical short circuit can be prevented. In addition, the bonding layer in the pattern part 222 may also be spaced a predetermined distance from an adjacent bonding layer.

In addition, in the camera device, the blocking layer EMI may be disposed on the inner side of the reinforcement layer ST. In addition, the reinforcement layer ST may have any structure which is positioned on an outer side of the pattern part 222 and has a pattern with separation spaces as in the drawings or covers the entire pattern part 222. For example, the reinforcement layer ST may be positioned in the separation space between adjacent conductive layers. This may be applied to the blocking layer EMI.

In addition, a width W2 of the conductive layer according to the embodiment may be smaller than or equal to a width or a separation distance W1 between the adjacent conductive layers. According to such a structure, the adjacent conductive layers in the pattern part 222 may be easily prevented from being in contact with each other.

Referring to FIG. 20A, in the connecting substrate according to the embodiment, the pattern part may be formed of the plurality of layers. In the connecting substrate, the pattern part may include the conductive layer (first conductive layer) L1 and the bonding layer (first bonding layer) P1 extending from the sensor substrate.

In addition, in the connecting substrate, the pattern part may include the reinforcement layer ST disposed on the first bonding layer P1. In addition, the pattern part may include the blocking layer EMI positioned under the first conductive layer L1. Based on the side surface of the housing, the blocking layer EMI, the first conductive layer L1, the first bonding layer P1, and the reinforcement layer ST may be disposed sequentially from the inside to the outside.

In addition, a height of the first conductive layer L1 may be greater than a height of the first bonding layer P1. In addition, a height H1 of the first conductive layer L1 may be greater than heights H2, H3, and H4 of the blocking layer EMI and the reinforcement layer ST, respectively.

Referring to FIG. 20B, in a pattern part according to a modified embodiment, an insulating layer IL may be further disposed between adjacent patterns. For example, the insulating layer IL may be disposed on side surfaces of a blocking layer EMI, a first conductive layer L1, a first bonding layer P1, and a reinforcement layer ST. In addition, the insulating layer IL may only be disposed between adjacent first conductive layers L1. That is, the insulating layer IL may be positioned between patterns of the first conductive layers L1. Accordingly, even when a connecting substrate shifts in response to shift of sensor substrate, electrical connection (short circuit) between adjacent conductive layers may be blocked by the insulating layer IL. Accordingly, the electrical reliability of a camera device can be improved.

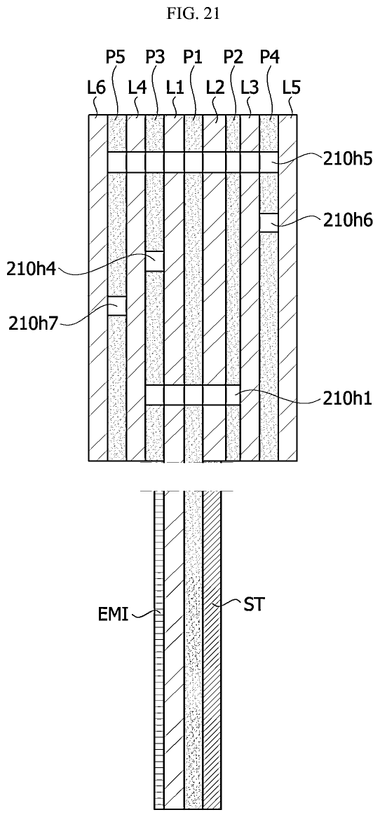

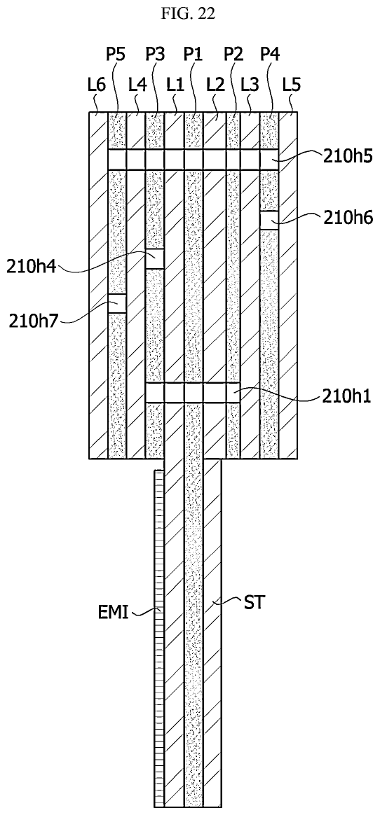

FIG. 21 is a cross-sectional view of a connecting substrate and a sensor substrate in a camera device according to a second embodiment, and FIG. 22 is a view of a modified embodiment of FIG. 21.

Referring to FIG. 21, the number of conductive layers of the sensor substrate in the camera device according to the second embodiment may be greater than the number of the conductive layers of the sensor substrate according to the first embodiment. For example, in the camera device according to the first embodiment, the number of the conductive layers in the sensor substrate may be four, and the number of the conductive layer in the connecting substrate may be one. In the camera device according to the second embodiment, the number of the conductive layers in the sensor substrate may be six, and the number of conductive layers in the connecting substrate may be one.

Unlike the camera device according to the above-described embodiment, the sensor substrate may further include a fifth conductive hole 210h5, a sixth conductive hole 210h6, and a seventh conductive hole h7. In the present embodiment, the sensor substrate may also include the first to fourth conductive holes.

In addition, the sensor substrate may include a fourth bonding layer P4 positioned on a third conductive layer L3, a fifth conductive layer L5 positioned on the fourth bonding layer P4, a fifth bonding layer P5 positioned under a fourth conductive layer L4, and a sixth conductive layer L6 positioned under the fifth bonding layer P5.

The fifth conductive hole 210h5 may electrically connect the fifth conductive layer L5 and the sixth conductive layer L6. The sixth conductive hole 210h6 may electrically connect the fifth conductive layer L5 and the third conductive layer L3. The seventh conductive hole 201h7 may electrically connect the sixth conductive layer L6 and the fourth conductive layer L4.

In addition, as described above, a pattern part 222 may include layers that are the same as a first conductive layer and a first bonding layer of the sensor substrate. That is, one conductive layer and one bonding layer of the sensor substrate may extend to the connecting substrate. In addition, one layer may be divided into a plurality of patterns when viewed from above. The conductive layer of each pattern may serve as one electrical line. In addition, the patterns in the conductive layer may have spaces spaced apart from each other. The same description may be applied to this.

Referring to FIG. 22, in a sensor substrate in a camera device according to a modified embodiment, the number of conductive layers may be greater than the number of the conductive layers in the sensor substrate according to the first embodiment. For example, in the camera device according to the first embodiment, the sensor substrate may have four conductive layers, and the connecting substrate may have one conductive layer. In the camera device according to the second embodiment, the sensor substrate may have six conductive layers, and the connecting substrate may have one conductive layer.

Unlike the camera device according to the above-described embodiment, the sensor substrate may include a fifth conductive hole 210h5, a sixth conductive hole 210h6, and a seventh conductive hole h7. In the present embodiment, the sensor substrate may also include a first conductive hole to a fourth conductive hole.

In addition, the sensor substrate may include a fourth bonding layer P4 positioned on a third conductive layer L3, a fifth conductive layer L5 positioned on the fourth bonding layer P4, a fifth bonding layer P5 positioned under a fourth conductive layer L4, and a sixth conductive layer L6 positioned under the fifth bonding layer P5.

The fifth conductive hole 210h5 may electrically connect the fifth conductive layer L5 and the sixth conductive layer L6. The sixth conductive hole 210h6 may electrically connect the fifth conductive layer L5 and the third conductive layer L3. The seventh conductive hole 201h7 may electrically connect the sixth conductive layer L6 and the fourth conductive layer L4.

In addition, as described above, a pattern part 222 may include layers that are the same as a first conductive layer and a first bonding layer of the sensor substrate. That is, one conductive layer and one bonding layer of the sensor substrate may extend to a connecting substrate. In addition, one layer may be divided into a plurality of patterns when viewed from above. The conductive layer of each pattern may serve as one electrical line. In addition, the patterns in the conductive layer may have spaces spaced apart from each other. The same description may be applied to this.

In addition, a second conductive layer L2 may be replaced with a reinforcement layer ST. That is, the second conductive layer L2 may be formed of an alloy material like the reinforcement layer ST. According to such a structure, the rigidity of the connecting substrate and the sensor substrate can be improved. Accordingly, the structural reliability of the sensor substrate and the connecting substrate can be improved.

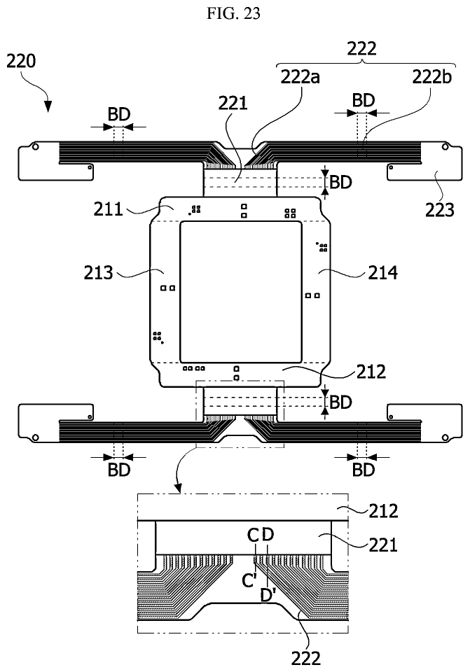

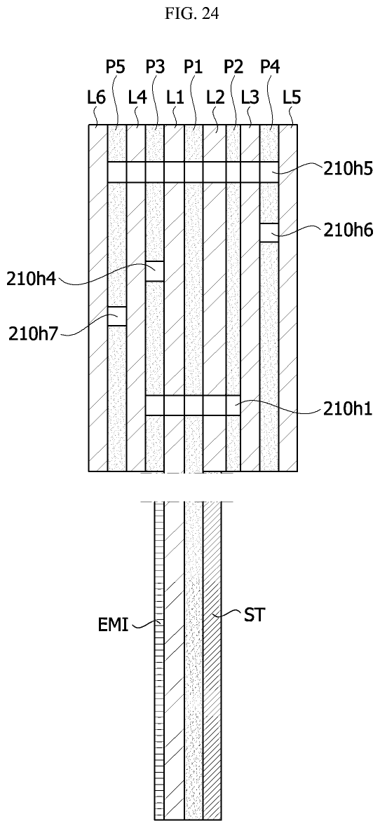

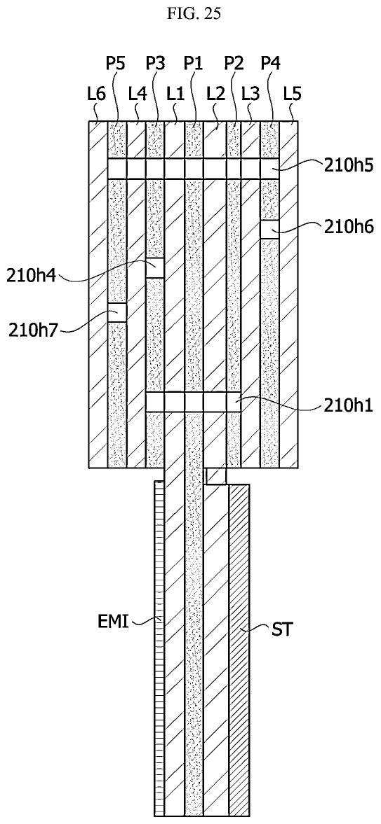

FIG. 23 is a plan view of a connecting substrate and a sensor substrate in a camera device according to a third embodiment, FIG. 24 is a cross-sectional view along line CC′ in FIG. 23, and FIG. 25 is a cross-sectional view along line DD′ in FIG. 23.

Referring to FIGS. 23 to 25, in the camera device according to the third embodiment, the number of conductive layers of the sensor substrate may be greater than the number of conductive layers of the sensor substrate according to the first embodiment. For example, in the camera device according to the first embodiment, the number of the conductive layers in the sensor substrate may be four, and the number of the conductive layers in the connecting substrate may be one. In the camera device according to the second embodiment, the number of conductive layers in the sensor substrate may be six, and the number of the conductive layer in the connecting substrate may be one.

Unlike the camera device according to the above-described embodiment, the sensor substrate may include a fifth conductive hole 210h5, a sixth conductive hole 210h6, and a seventh conductive hole h7. In the present embodiment, the sensor substrate may also include a first conductive hole to a fourth conductive hole.

In addition, the sensor substrate may include a fourth bonding layer P4 positioned on a third conductive layer L3, a fifth conductive layer L5 positioned on the fourth bonding layer P4, a fifth bonding layer P5 positioned under a fourth conductive layer L4, and a sixth conductive layer L6 positioned under the fifth bonding layer P5.

The fifth conductive hole 210h5 may electrically connect the fifth conductive layer L5 and the sixth conductive layer L6. The sixth conductive hole 210h6 may electrically connect the fifth conductive layer L5 and the third conductive layer L3. The seventh conductive hole 201h7 may electrically connect the sixth conductive layer L6 and the fourth conductive layer L4.

In addition, as described above, a pattern part 222 may include layers that are the same as a first conductive layer and a first bonding layer of the sensor substrate. In addition, a pattern part may further include an additional conductive layer in addition to the first conductive layer. The pattern part may have a plurality of conductive layers. In addition, the conductive layer and the bonding layer of the sensor substrate may extend to the connecting substrate. In addition, one layer may be divided into a plurality of patterns when viewed from above. The conductive layer of each pattern may serve as one electrical line. In addition, the patterns in the conductive layer may have spaces spaced apart from each other. The same description may be applied to this.

In addition, in the present embodiment, the plurality of conductive layers may be positioned in the connecting substrate. In addition, the plurality of conductive layers may be divided into a plurality of patterns. Accordingly, in adjacent patterns, the conductive layers may be positioned on different layers. For example, a first conductive layer L1 and a second conductive layer L2 may be positioned in each adjacent pattern. Accordingly, in the adjacent patterns, the conductive layers may be spaced apart from each other in a second direction or third direction, and may also be spaced apart from each other in a thickness direction. According to such a structure, even when the above-described insulating layer is not present, electrical connection (short circuit) between the conductive layers in the adjacent patterns can be easily blocked.

In addition, a reinforcement layer ST and a blocking layer EMI may be positioned on an outermost side and an innermost side, respectively. In addition, positions of the reinforcement layer ST and the blocking layer EMI may be changed from the outermost side and the innermost side according to a case.

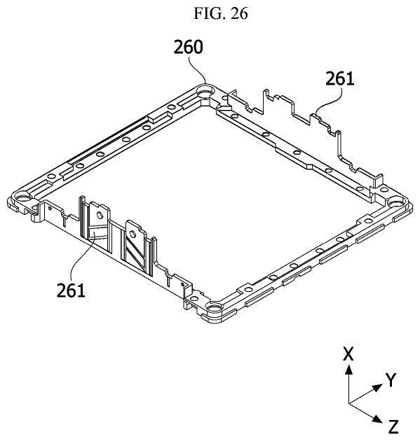

FIG. 26 is a perspective view of the base according to the embodiment.

### <Base>

Referring to FIG. 26, an opening region or through hole may be formed in a central portion of the base 260. The above-described sensor substrate, image sensor, and the like may be positioned in the opening region or through hole.

In addition, a hole for connection with the elastic connection part may be positioned at each corner of the base 260. However, as described above, the elastic connection part may connect the substrate part and the housing. In addition, the base 260 may include base support parts 261 extending upward from an outer surface of the base 260 and facing in the second direction (Y-axis direction). In addition, the base support parts 261 may be disposed in parallel in the third direction.

The base support part 261 may extend upward from the outer surface of the base 260. A part of the pattern part of the connecting substrate and the second connecting part may be positioned outside the base support part 261.

In addition, the base support part 261 may be positioned between the second housing step of the housing and the outer surface of the housing. That is, the base support part may be positioned in a space formed due to the bent second housing step. In addition, the connecting substrate outside the base support part 261 may be positioned in the space formed due to the above-described bent second housing step. According to such a structure, the connecting substrate may be protected by the second housing step. In addition, the base support part 261 may support and be connected to the housing.

In addition, the base 260 may be disposed on and coupled to the main substrate. Accordingly, the base 260 may guide arrangement positions at which the sensor substrate and the extension substrate are seated.

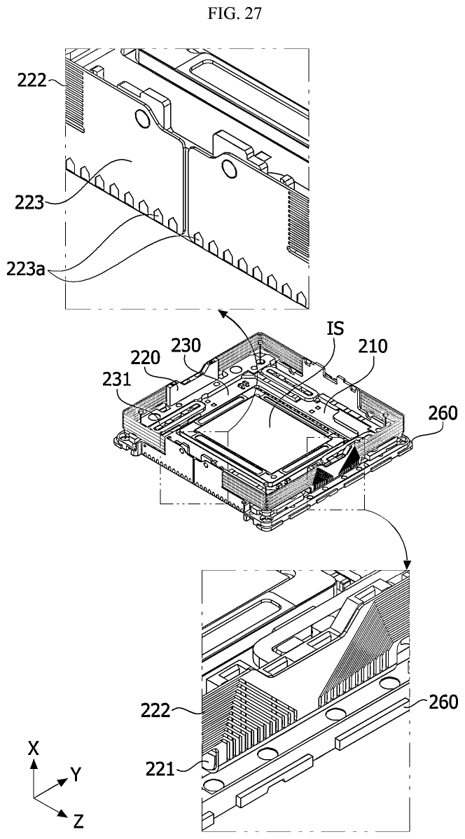

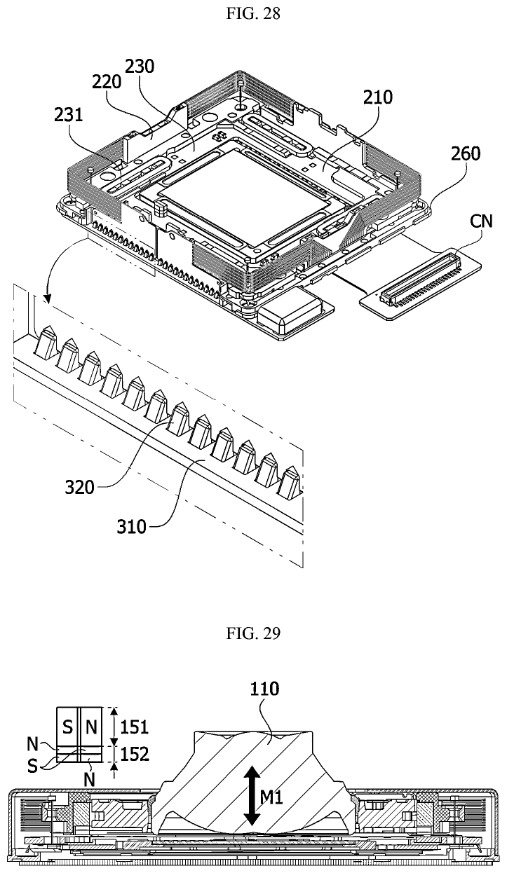

FIG. 27 is a perspective view of the second actuator according to the embodiment, and FIG. 28 is a perspective view of the second actuator and the main substrate according to the embodiment.

Referring to FIGS. 27 and 28, the connecting terminals 223a to 223d may be positioned on outer surfaces of the second connecting part 223 on the connecting substrate 220. The plurality of connecting terminals that are described above may be positioned on the outer surfaces of the second connecting part 223 that are spaced apart from each other.

In addition, the connecting terminals 223a to 223d may be electrically connected to the terminal part 320 positioned on an edge of the main substrate part 310 of the main substrate 300 positioned under the connecting terminals 223a to 223d. Distances between adjacent terminal parts 320 may be different according to regions like the connecting terminals spaced apart from each other.

In addition, the terminal parts 320 may extend upward. In addition, the terminal parts 320 and the connecting terminals 223a to 223d may be easily connected by soldering or the like. In addition, the terminal parts 320 may protect the inner connecting terminals. In addition, the number of the connecting terminals 223a to 223d may be the same as the number of the terminal parts 320. According to such a structure, a signal received from the image sensor IS, a signal for driving the first and second coils, a position signal of the lens, a position signal of the image sensor, and the like may be transmitted to and received from a processor or control unit in the electronic device through the connector part CN.

In addition, as described above, the first connecting part 221 may be positioned between the pattern part 222 and the second connecting part 223 on the connecting substrate 210. In addition, a plurality of first connecting parts 221 may overlap in the third direction (Z-axis direction). For example, two first connecting parts 221 may overlap in the third direction (Z-axis direction).

In addition, two pattern parts 222 extend from one first connecting part 221, and the pattern part 222 may have a symmetrical structure in the second direction or the third direction. The second connecting parts 223 may be symmetrically disposed in the third direction (Z-axis direction) or the second direction (Y-axis direction). According to such a structure, the structural stability of the substrate part can be improved. Accordingly, accuracy can be improved when AF/OIS is operated.

In addition, as illustrated and described above, in the pattern part 222, an extending direction of the electrical line may be changed vertically. In addition, the extending direction of the electrical line may be changed according to the bending region.

FIGS. 29 to 31 are views for describing operations of the camera device according to the embodiment.

### <Camera Device Operation>

Referring to FIG. 29, as described above, the lens holder and the lens 110 may move in the optical axis direction according to a flow direction of a current in the first coil (M1). In addition, when a current does not flow through the first coil, the lens 110 may be positioned at a predetermined level due to the first elastic part.

The first magnet 151 and the first coil are a driving source for an operation of the lens 110 in the optical axis direction, that is, an AF operation. At least a part of the first magnet 151 may overlap the first coil on the YZ plane.

In addition, polarities, which are positioned at the inner sides, of the first magnets 151 may be the same. In other words, the first magnets 151 may be positioned in the plurality of inner grooves positioned in the inner surface of the housing, and the same polarities of the plurality of first magnets may be positioned at the inner side. Accordingly, the first magnets 151 may provide a magnetic force in any one direction of a direction toward the first coils and a direction toward the first magnets from the first coils. Accordingly, the first coils surrounding an outer side of the lens 110 (or lens holder) may receive a magnetic force in a predetermined direction. Accordingly, when a current flows through the first coils, an electromagnetic force may be generated in the first coils by the above-described current and magnetic force. The electromagnetic force may be generated vertically in the optical axis direction.

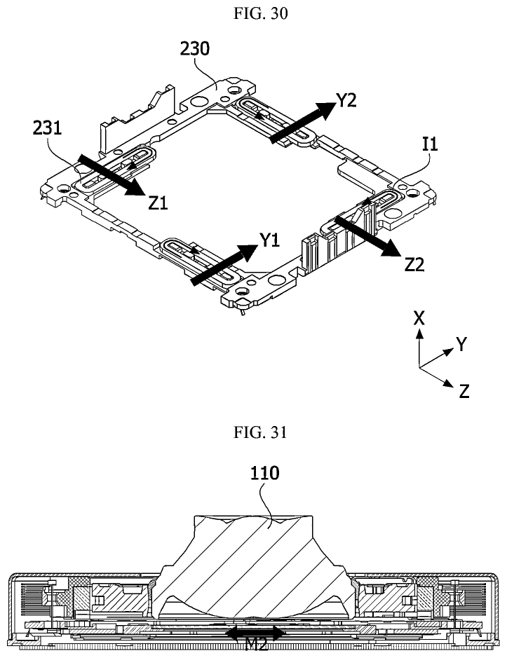

In addition, further referring to FIGS. 30 and 31, movement or shift operation of the image sensor will be described. As illustrated in the drawings, the image sensor IS may move or rotate in a direction perpendicular to the optical axis (M2).

As described above, in the camera device according to the embodiment, a Lorentz force, which is an electromagnetic force, may be generated by a magnetic force between a magnet and a coil and a current flow.

For example, as illustrated in the drawings, a current I1 may flow in each second coil as illustrated. In addition, a lower inner polarity of the second magnet 152 may be an N-pole, and an outer polarity may be an S-pole.

In the embodiment, when a current is applied to each of the third sub-coil and the fourth sub-coil in an illustrated direction, the image sensor IS coupled to the image sensor module 400 may be moved (shifted) in the Y-axis direction by an electromagnetic interaction with the second magnet. That is, the third sub-coil and the second magnet, and the fourth sub-coil and the second magnet may be used for the shift operation of the image sensor IS in the Y-axis direction. In this case, the third sub-coil and the second magnet may be a 2a axis shift driving part Y1, and the fourth sub-coil and the second magnet may be a 2b axis shift driving part Y2.

When a current is applied to each of the first sub-coil and the second sub-coil in an illustrated direction, the image sensor IS coupled to the sensor substrate may be moved (shifted) in the Z-axis direction by an electromagnetic interaction with the second magnet. That is, the first sub-coil and the second magnet, and the second sub-coil and the second magnet may be used for the shift operation of the image sensor IS in the Z-axis direction shift. In this case, the first sub-coil and the second magnet may be a 3x axis shift driving part Z1, and the second sub-coil and the second magnet may be a 3y axis shift driving part Z2.

In addition, a current may be applied to the first sub-coil and the second sub-coil in the same direction (any one of a clockwise direction and a counterclockwise direction), or a current may be applied to the third sub-coil and the fourth sub-coil in the same direction. In this case, the image sensor IS coupled to the sensor substrate may be rotated (rolled) around the X axis by the current applied to each sub-coil.

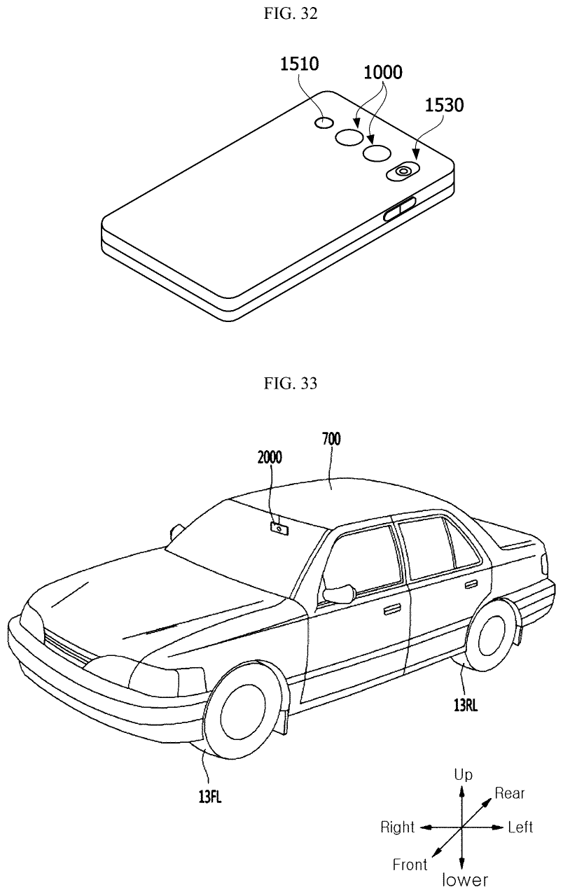

FIG. 32 is a perspective view of a mobile terminal to which the camera device according to the embodiment is applied.

Referring to FIG. 32, a mobile terminal 1500 in the embodiment may include the camera device 1000, a flash module 1530, and an AF device 1510 which are provided on a rear surface of the mobile terminal 1500.

The camera device 1000 may have an image capturing function and an AF function. For example, the camera device 1000 may have an AF function using an image.

The camera device 1000 processes a still image or image frames of moving images obtained through an image sensor in an image capturing mode or video call mode.

The processed image frames may be displayed on a predetermined display and stored in a memory. A camera (not shown) may be disposed on a front surface of a body of a mobile terminal.

For example, the camera device 1000 may include a first camera device 1000a and a second camera device 1000b, and an AF or zoom function and OIS may be implemented by the first camera device 1000a. In addition, the second camera device 1000b may perform an AF or zoom function and an OIS function. In addition, AF, zoom, and OIS functions may be implemented using the second camera device 1000b. In this case, since the first camera device 1000A includes both a first camera actuator and a second camera actuator, the camera device can be easily miniaturized by changing an optical path.

The flash module 1530 may include a light-emitting element which emits light therein. The flash module 1530 may be operated by operation of a camera of the mobile terminal or control of a user.

The AF device 1510 may include one of surface light-emitting laser element packages as a light-emitting part.

The AF device 1510 may have an AF function using a laser. The AF device 1510 may be mainly used in a condition in which the performance of the AF function using the image of the camera device 1000 is degraded, for example, in a close environment within 10 m or less or in a dark environment.

The AF device 1510 may include a light-emitting part, which includes a vertical-cavity surface-emitting laser (VCSEL) semiconductor element, and a light-receiving part, which converts light energy into an electrical energy, like a photodiode.

FIG. 33 is a view of a vehicle to which the camera device according to the embodiment is applied.

For example, FIG. 33 is an exterior view of a vehicle including a vehicle driving auxiliary device to which the camera device 1000 according to the embodiment is applied.

Referring to FIG. 33, a vehicle 700 of the embodiment may include wheels 13FL and 13FR, which are rotated by a power source, and a predetermined sensor. Although the sensor may be a camera sensor 2000, the present invention is not limited thereto.

The camera 2000 may be a camera sensor to which the camera device 1000 according to the embodiment is applied. The vehicle 700 of the embodiment may obtain image information through the camera sensor 2000 which captures a forward image or nearby images, determine a situation in which lanes are not identified, using the image information, and generate virtual lanes when the lanes are not identified.

For example, the camera sensor 2000 may obtain the forward image by capturing an image in front of the vehicle 700, and a processor (not shown) may analysis objects included in the forward image to obtain the image information.

For example, when images of objects such as lanes, adjacent vehicles, road obstacles, and indirect road indicators such as median strips, curb stones, and street trees are captured in an image captured by the camera sensor 2000, the process may detect such objects so that the objects are included in the image information. In this case, the processor may obtain distance information from the objects detected through the camera sensor 2000 to supplement the image information.

The image information may be information about the objects of which the images are captured. The camera sensor 2000 may include an image sensor and an image processing module.

The camera sensor 2000 may process a still image or moving images obtained by the image sensor (for example, CMOS or CCD).

The image processing module may extract necessary information by processing the still image or moving images obtained through the image sensor and transmit the extracted information to the processor.

In this case, the camera sensor 2000 may further include a stereo camera in order to improve measurement accuracy of an object and further secure information of a distance between the vehicle 700 and the object and the like but is not limited thereto.

In addition, the camera device or camera module may be applied to an electronic device or optical device. The electronic device or optical device may be any one among a mobile phone, a portable phone, a smart phone, a portable smart device, a digital camera, a laptop computer, a digital broadcasting terminal, a personal digital assistant (PDA), a portable multimedia player (PMP), and a navigation system. However, the types of optical devices are not limited thereto, and any device for capturing videos or images may be included in the optical device.

While the present invention has been mainly described above with reference to embodiments, it will be understood by those skilled in the art that the present invention is not limited to the embodiments, the embodiments are only exemplary, and various modifications and applications, which are not exemplified above, may be made in the range of the present invention without departing from the essential features of the present embodiments. For example, components specifically described in the embodiments may be implemented with modifications. In addition, it should be interpreted that differences related to such modifications and applications fall in the scope of the present invention defined by the appended claims.

1. A camera device comprising:
a lens holder that accommodates a lens;
a housing that surrounds the lens holder;
a substrate part including a sensor substrate on which an image sensor is mounted under the housing and a connecting substrate connected to the sensor substrate;
a base disposed under the substrate part; and
a main substrate disposed under the base,
wherein a thickness of the connecting substrate is different from a thickness of the sensor substrate.

2. The camera device of claim 1, wherein the thickness of the connecting substrate is smaller than the thickness of the sensor substrate.

3. The camera device of claim 1, wherein the sensor substrate includes:
a plurality of conductive layers; and
a plurality of bonding layers disposed between or on the plurality of conductive layers.

4. The camera device of claim 3,
wherein the sensor substrate shares one conductive layer among the plurality of conductive layers; and
wherein the shared one conductive layer overlaps the sensor substrate and the connecting substrate.

5. The camera device of claim 3,
wherein the sensor substrate shares one bonding layer among the plurality of conductive layers; and
wherein the shared bonding layer overlaps the sensor substrate and the connecting substrate.

6. The camera device of claim 1, wherein the connecting substrate includes:
a first connecting part of which one end is in contact with the sensor substrate;
a second connecting part connected to the main substrate; and
a pattern part disposed between the first connecting part and the second connecting part.

7. The camera device of claim 6,
wherein the pattern part includes a first conductive layer shared with the sensor substrate; and
wherein the first conductive layer is formed of a plurality of conductive patterns with a separation space therebetween.

8. The camera device of claim 7, wherein the pattern part includes an insulating layer disposed between adjacent first conductive layers.

9. The camera device of claim 7, wherein the pattern part includes a first bonding layer shared with the sensor substrate.

10. The camera device of claim 10, wherein the first bonding layer is in contact with the first conductive layer and is disposed on an inner side of the first conductive layer.

11. The camera device of claim 9,
wherein the pattern part includes a reinforcement layer disposed on the first conductive layer.

12. The camera device of claim 11,
wherein the pattern part includes a blocking layer disposed under the first bonding layer.

13. The camera device of claim 12,
wherein the reinforcement layer is disposed outside the blocking layer.

14. The camera device of claim 6,
wherein the first connecting part is positioned inside a lower portion of the pattern part.

15. The camera device of claim 6,
wherein the pattern part surrounds the housing.

16. The camera device of claim 1,
wherein the main substrate is coupled to the base using a bonding member.

17. The camera device of claim 6,
wherein the pattern part includes a first sub-pattern part extending in a first direction and a second sub-pattern part extending to surround a side surface of the housing.

18. The camera device of claim 17,
wherein one of two ends of the first sub-pattern part is in contact with the sensor substrate, and the other end thereof is in contact with the second sub-pattern part.

19. The camera device of claim 17,
wherein one of two ends of the second sub-pattern part is in contact with the first sub-pattern part, and the other end thereof is in contact with the second connecting part.

20. The camera device of claim 6,
wherein the sensor substrate includes first to fourth edge regions other than the image sensor, and
wherein the first connecting part includes a bending region extending from the first edge region and the second edge region.
